(19) United States
(12) Patent Application Publication
(10) Pub. No.: US 2025/0280589 A1
(43) Pub. Date: Sep. 4, 2025

(54) ELECTRONIC DEVICE INCLUDING A POWER TRANSISTOR

(71) Applicant: SEMICONDUCTOR COMPONENTS INDUSTRIES, LLC, Scottsdale, AZ (US)

(72) Inventors: Gary Horst LOECHELT, Tempe, AZ (US); Tanuj SAXENA, Chandler, AZ (US)

(73) Assignee: SEMICONDUCTOR COMPONENTS INDUSTRIES, LLC, Scottsdale, AZ (US)

(21) Appl. No.: 19/025,046

(22) Filed: Jan. 16, 2025

Related U.S. Application Data
(60) Provisional application No. 63/560,318, filed on Mar. 1, 2024.

(51) Int. Cl. H10D 64/27; H10D 12/00; H10D 30/66

(52) U.S. Cl. CPC H10D 64/513; H10D 12/481; H10D 30/668

(57) ABSTRACT

An electronic device can include a transistor structure including a carrier accumulation region, a buried region, and a gap region. The transistor structure has a lateral dimension corresponding to how far the buried region extends toward the gap region and a vertical dimension corresponding to the thickness of the carrier accumulation region. An aspect ratio can be the lateral dimension to the vertical dimension, wherein the aspect ratio is at least 1.5:1. A power transistor can have a buried shield-to-gap ratio that can be at least 2:1. The electronic device can include a link region that can electrically couple the body region to the buried shield. A source region can overlap at least part of the link region. A power transistor can withstand to short-circuit event for a relatively longer time as compared to a conventional power transistor.

### CROSS REFERENCE TO RELATED APPLICATION

This application claims priority under 35 U.S.C. § 119(e) to U.S. Patent Application No. 63/560,318 entitled “Electronic Device Including a Power Transistor,” by Loechelt et al., filed Mar. 1, 2024, which is assigned to the current assignee hereof and incorporated herein by reference in its entirety.

### FIELD OF THE DISCLOSURE

The present disclosure relates to electronic devices, and more particularly, to electronic devices that include power transistors.

### RELATED ART

Transistors can be designed to operate at relatively high voltages and high currents. Some semiconductor materials, such as monocrystalline Si, may not be able to operate at such high voltages and currents or may need complex designs to withstand the high voltages and current during operation. Wide band gap semiconductors such as SiC can be used in transistors that operate at high voltages and current. Specific on-state resistance (R_{SP}) may be higher than desired, and scaling transistors to smaller dimensions can be challenging. Further improvements in reducing R_{SP} and reducing dimensions are desired.

### BRIEF DESCRIPTION OF THE DRAWINGS

Implementations are illustrated by way of example and are not limited in the accompanying figures.

FIG. 1 includes an illustration of a cross-sectional view of a portion of a workpiece that includes a substrate that includes a semiconductor base material and a semiconductor layer.

FIG. 2 includes an illustration of a cross-sectional view of the workpiece of FIG. 1 after forming a carrier distribution layer and a carrier accumulation region.

FIGS. 3 to 6 include illustrations of a top view and cross-sectional views of the workpiece of FIG. 2 after forming a buried shield mask and a buried shield in accordance with Design 1.

FIGS. 7 to 10 include illustrations of a top view and cross-sectional views of the workpiece of FIGS. 3 to 6 after forming a body/source mask, a body region, and a source region in accordance with Design 1.

FIGS. 11 to 14 include illustrations of a top view and cross-sectional views of the workpiece of FIGS. 7 to 10 after forming a body contact mask and body contact regions in accordance with Design 1.

FIGS. 15 to 18 include illustrations of a top view and cross-sectional views of the workpiece of FIGS. 11 to 14 after forming a link mask and link regions in accordance with Design 1.

FIGS. 19 to 22 include illustrations of a top view and cross-sectional views of the workpiece of FIGS. 15 to 18 after forming a gate trench mask, gate trenches, a gate dielectric layer, and gate electrodes in accordance with Design 1.

FIGS. 23 to 26 include illustrations of a top view and cross-sectional views of the workpiece of FIGS. 19 to 22 after forming an interlevel dielectric layer, a contact mask, and a source terminal in accordance with Design 1.

FIG. 27 includes an illustration of a cross-sectional view of transistor structures to illustrate majority carrier flow from the source region to the semiconductor layer via a gap in the buried shield.

FIGS. 28 to 31 include illustrations of a top view and cross-sectional views of the workpiece of FIG. 2 after forming a buried shield mask and a buried shield in accordance with Design 2.

FIGS. 32 to 35 include illustrations of a top view and cross-sectional views of the workpiece of FIGS. 28 to 31 after forming a body/source mask, a body region, and a source region in accordance with Design 2.

FIGS. 36 to 39 include illustrations of a top view and cross-sectional views of the workpiece of FIGS. 32 to 35 after forming a body contact mask and body contact regions in accordance with Design 2.

FIGS. 40 to 43 include illustrations of a top view and cross-sectional views of the workpiece of FIGS. 36 to 39 after forming a link mask and link regions in accordance with Design 2.

FIGS. 44 to 47 include illustrations of a top view and cross-sectional views of the workpiece of FIGS. 40 to 43 after forming a gate trench mask and gate trenches, a gate dielectric layer, and gate electrodes in accordance with Design 2.

FIGS. 48 to 51 include illustrations of a top view and cross-sectional views of the workpiece of FIGS. 44 to 47 after forming an interlevel dielectric layer, a contact mask, and a source terminal in accordance with Design 2.

FIGS. 52 to 54 include illustrations of a top view and cross-sectional views of the workpiece of FIG. 2 after forming a buried shield mask and buried shields in accordance with Design 3.

FIGS. 55 to 58 include illustrations of a top view and cross-sectional views of the workpiece of FIGS. 52 to 54 after forming a body/source mask, a body region, and a source region in accordance with Design 3.

FIGS. 59 to 62 include illustrations of a top view and cross-sectional views of the workpiece of FIGS. 55 to 58 after forming a body contact mask and body contact regions in accordance with Design 3.

FIGS. 63 to 66 include illustrations of a top view and cross-sectional views of the workpiece of FIGS. 59 to 62 after forming a link mask and link regions in accordance with Design 3.

FIGS. 67 to 70 include illustrations of a top view and cross-sectional views of the workpiece of FIGS. 63 to 66 after forming a gate trench mask and gate trenches, a gate dielectric layer, and gate electrodes in accordance with Design 3.

FIGS. 71 to 74 include illustrations of a top view and cross-sectional views of the workpiece of FIGS. 67 to 70 after forming an interlevel dielectric layer, a contact mask, and a source terminal in accordance with Design 3.

FIGS. 75 to 77 include illustrations of a top view and cross-sectional views of the workpiece of FIG. 2 after forming a buried shield mask and buried shields in accordance with Design 4.

FIGS. 78 to 81 include illustrations of a top view and cross-sectional views of the workpiece of FIGS. 75 to 77 after forming a body/source mask, a body region, and a source region in accordance with Design 4.

FIGS. 82 to 85 include illustrations of a top view and cross-sectional views of the workpiece of FIGS. 78 to 81 after forming a body contact mask and body contact regions in accordance with Design 4.

FIGS. 86 to 89 include illustrations of a top view and cross-sectional views of the workpiece of FIGS. 82 to 85 after forming a link mask and link regions in accordance with Design 4.

FIGS. 90 to 93 include illustrations of a top view and cross-sectional views of the workpiece of FIGS. 86 to 89 after forming a gate trench mask and gate trenches, a gate dielectric layer, and gate electrodes in accordance with Design 4.

FIGS. 94 to 97 include illustrations of a top view and cross-sectional views of the workpiece of FIGS. 90 to 93 after forming an interlevel dielectric layer, a contact mask, and a source terminal in accordance with Design 4.

Skilled artisans appreciate that elements in the figures are illustrated for simplicity and clarity and have not necessarily been drawn to scale. For example, the dimensions of some of the elements in the figures may be exaggerated relative to other elements to help to improve understanding of implementations of the inventive concepts.

### DETAILED DESCRIPTION

The following description in combination with the figures is provided to assist in understanding the teachings disclosed herein. The following description will focus on specific implementations of the teachings. This focus is provided to assist in describing the teachings and should not be interpreted as a limitation on the scope or applicability of the teachings. However, other implementations can be used based on the teachings as disclosed in this application.

As used in this specification, length and width are measured in directions along or parallel to a major surface of a substrate or a semiconductor layer. Depth, height, and thickness are measured in directions perpendicular to the major surface of the substrate or the semiconductor layer.

The term “electrically coupled” is intended to mean a connection, linking, or association of two or more electronic components, circuits, systems, or any combination of: (1) at least one electronic component, (2) at least one circuit, or (3) at least one system in such a way that a signal (e.g., current, voltage, or optical signal) may be partly or completely transferred from one to another. A subset of “electrically coupled” can include an electrical connection between two electronic components. In a circuit diagram, a node corresponds to an electrical connection between the electronic components. Thus, an electrical connection is a specific type of electrical coupling; however, not all electrical couplings are electrical connections. Other types of electrical coupling include capacitive coupling, resistive coupling, and inductive coupling.

The terms “horizontal,” “lateral,” and their variants are in directions along or parallel to a major surface of a substrate or semiconductor layer, and the terms “vertical,” “height,” “depth,” and their variants are in directions perpendicular to a major surface of the substrate or the semiconductor layer. Two objects that are laterally offset can be at the same or different elevations.

The term “normal operation” and “normal operating conditions” refer to conditions under which an electronic component or device is designed to operate. The conditions may be obtained from a data sheet or other information regarding voltages, currents, capacitance, resistance, or other electrical conditions. Thus, normal operation does not include operating an electrical component or device well beyond its design limits.

The terms “overlap,” “underlap,” and their variants refer to at least portions of regions or other features that lie along a vertical line that is perpendicular to a plane defined by a major surface. Components or features that overlap or underlap each other may or may not be in physical contact with each other.

The terms “power transistor” is intended to mean a transistor that has a drain-to-source breakdown voltage (BVDs) of at least 400 V.

Unless explicitly stated to the contrary, a border between a relatively heavier doped region or layer and an immediately adjacent and relatively lighter doped region or layer of the same conductivity type is where the dopant concentration between the regions or layers is 1.1 times higher than a peak dopant concentration of the relatively lower doped region or layer.

The terms “on,” “overlying,” and “over” may be used to indicate that two or more elements are in direct physical contact with each other. However, “over” may also mean that two or more elements are not in direct contact with each other. For example, “over” may mean that one element is above another element, but the elements do not contact each other and may have another element or elements between the two elements.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is used when describing elements, components and other features described herein. This is done merely for convenience and to give a general sense of the scope of the inventive concepts. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Thus, differences of up to ten percent (10%) (and up to twenty percent (20%) for semiconductor doping concentrations) for the value are reasonable differences from the ideal goal of exactly as described.

Unless otherwise defined, all technical and scientific terms used herein have the same meaning as commonly understood by one of ordinary skill in the art to which these inventive concepts belongs. The materials, methods, and examples are illustrative only and not intended to be limiting. To the extent not described herein, many details regarding specific materials and processing acts are conventional and may be found in textbooks and other sources within the semiconductor and electronic arts.

An electronic device can include a transistor structure that includes a body region, a carrier accumulation region, a buried region, and a gap region defined at least in part by the buried region. The transistor structure has a lateral dimension that corresponds generally to a distance that the buried region extends toward the gap region and a vertical dimension that corresponds generally to the thickness of the carrier accumulation region near a gate trench. In an implementation, an aspect ratio can be the lateral dimension to the vertical dimension, wherein the aspect ratio is at least 1.5:1. In the same or different implementation, the transistor can have a buried shield-to-gap ratio, which is a ratio of a portion of the buried shield width between immediately adjacent gap regions to the gap region width. The buried shield-to-gap ratio can be at least 2:1. In any of the preceding or a different implementation, the electronic device can include a link region that can electrically couple the body region to the buried shield. A source region can overlap at least part of the link region. A power transistor including the transistor structure can allow the power transistor to withstand to short-circuit event for a relatively longer time as compared to a conventional power transistor.

In an aspect, an electronic device, comprising a transistor structure, wherein the transistor structure comprises a substrate defining a gate trench that extends to a gate trench depth from a major surface of the substrate; a carrier accumulation region having a first conductivity type; a body region having a second conductivity type opposite the first conductivity type, wherein the body region overlaps the carrier accumulation region; a buried shield having the second conductivity type, wherein the buried shield is spaced apart from the body region by at least a portion of the carrier accumulation region; and a gap region having the first conductivity type, wherein the gap region is defined at least in part by the buried shield and has a gap region width that is a narrowest width of the gap region as measured in a measuring direction that is parallel to the major surface and perpendicular to the gate trench depth. The transistor structure can have an aspect ratio that is a ratio of a lateral dimension to a vertical dimension, wherein (1) the lateral dimension is measured in the measuring direction of the gap region and is a second distance between: a first point within the buried shield that underlaps an intersection of the body region, the carrier accumulation region, and the gate trench, and a second point where the buried shield within the transistor structure extends farthest toward the gap region, and (2) the vertical dimension is a first distance between the body region and the buried shield along the gate trench in a first direction perpendicular to the major surface. The aspect ratio can be at least 1.5:1.

In another aspect, an electronic device can include a substrate defining a gate trench that extends to a gate trench depth from a major surface of the substrate; a gap region having a first conductivity type, wherein the gap region has a gap region width that is a narrowest width of the gap region as measured in a measuring direction that is parallel to the major surface and perpendicular to the gate trench depth. The electronic device can further include a buried shield having a second conductivity type opposite the first conductivity type. The buried shield can have a buried shield width that is a widest width of the buried shield as measured in the measuring direction. The gap region is defined at least in part by the buried shield, and the buried shield can underlap the gate trench. A buried shield-to-gap ratio is a ratio of the buried shield width to the gap region width, and the buried shield-to-gap ratio is at least 2:1.

In a further aspect, an electronic device can include a source region having a first conductivity type; a body region having a second conductivity type opposite the first conductivity type and underlapping the source region; a carrier accumulation region having the first conductivity type and underlapping the body region; a buried shield having the second conductivity type and underlapping the carrier accumulation region; and a link region having the second conductivity type and electrically coupled to the body region and the buried shield. The source region can overlap at least part of the link region.

In the description below, doped layers and doped regions are described with respect to dopant concentrations and depths and vertical positions (in a direction perpendicular to a major surface) and lengths and widths (along the major surface or a plane parallel to the major surface). Skilled artisans will be able to perform simulations to determine doses and energies to be used at the time of doping to achieve the doped layers and doped regions in the finished device.

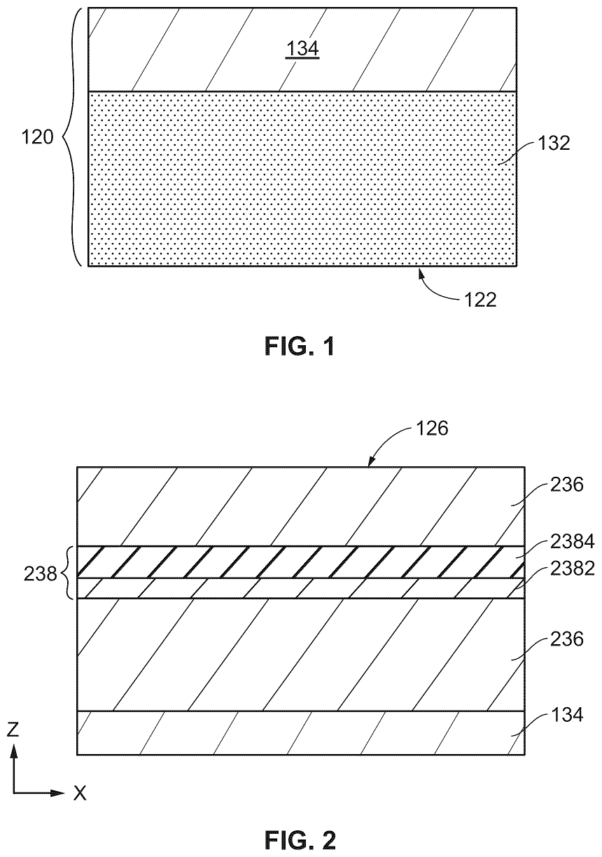

FIG. 1 includes a cross-sectional view of a portion of a substrate 120 that can include a semiconductor base material 132 and a semiconductor layer 134. The semiconductor base material 132 can be a monocrystalline semiconductor wafer, a semiconductor-on-insulator (SOI) wafer, or the like. In an implementation, the semiconductor base material 132 can be in a form of a wafer. The semiconductor base material 132 and the semiconductor layer 134 can include a wide bandgap semiconductor material, and in a particular implementation, SiC is the semiconductor material within the semiconductor layer 134 and is the semiconductor material within at least the portion of the semiconductor base material 132 that contacts the semiconductor layer 134. In an implementation, the SiC can be a 3C, a 4H, or a 6H polytype.

The semiconductor material within the semiconductor base material 132 can be a drain region for the power transistor and have a dopant concentration of at least 1×10¹⁸ atoms/cm³. In a particular implementation, the dopant concentration can be at least 1×10¹⁹ atoms/cm³ to ensure an ohmic contact to a drain electrode that is subsequently attached to or formed along a back side major surface 122. The semiconductor base material 132 may have a peak dopant concentration that is at most 2×10²¹ atoms/cm³. The semiconductor material within the semiconductor base material 132 can be n-type doped or p-type doped. The majority carriers for the power transistor can be electrons, and the semiconductor material can be n-type doped. In this specification, n-type dopants can be N or P, and a p-type dopant can be Al.

The semiconductor layer 134 can be epitaxially grown and doped during or after growth. The semiconductor layer 134 can have a thickness in a range from 4.0 microns to 20.0 microns. The semiconductor layer 134 can have the same conductivity type as the semiconductor material within the semiconductor base material 132. In an implementation, the semiconductor layer 134 is n-type doped. The semiconductor layer 134 can be a drift region for the power transistor and have a lower dopant concentration as compared to the semiconductor material within the semiconductor base material 132. The average dopant concentration of the semiconductor layer 134 can be in a range from 2×10¹⁵ atoms/cm³ to 4×10¹⁶ atoms/cm³. The average dopant concentration of the semiconductor layer 134 before any further doping, such as for a body region or a source region, is referred to herein as the background dopant concentration.

One or more epitaxial layers may be grown between semiconductor base material 132 and semiconductor layer 134. These additional layers may serve a number of functions including, such as, providing a transition buffer at the start of epitaxial growth, a layer for isolating crystal defects from the semiconductor layer 134, or a layer for improving stability at high current operation (i.e., safe operating area improvement). In these aforementioned cases, the additional layers usually have a higher doping concentration than semiconductor layer 134, have low resistivity because of their high doping concentration, and provide little additional benefit in blocking voltage.

A mask can be formed over the major surface 126 of the semiconductor layer 134. The active area for transistor structures of the power transistor being formed is exposed. The mask covers areas where electronic components and circuits are outside the active area for the transistor structures.

Referring to FIG. 2, doping can be performed to form a carrier distribution layer 236 and a carrier accumulation region 238. The order of formation of the carrier distribution layer 236 and the carrier accumulation region 238 can be performed in any order relative to one another.

In this specification, doping for each layer or region can be performed as a single ion implantation or as a plurality of ion implantations where each ion implant is performed at a different energy as compared to one or more other ion implantations within the plurality of ion implantations. After reading this specification, for each doping, skilled artisans will be able to determine the number of ion implantations, dose(s), and energy(ies) for a particular doping species (e.g., N (n-type), P (n-type), or Al (p-type)) to achieve desired doping depth(s) and a dopant concentration profile.

The carrier distribution layer 236 can help to redistribute majority carriers along a flow path from subsequently-formed carrier accumulation regions to the semiconductor layer 134 via subsequently defined gap regions. The carrier distribution layer 236 has the same conductivity type as the semiconductor layer 134. In an implementation, the carrier distribution layer 236 is n-type doped. The carrier distribution layer 236 can have a peak dopant concentration that is greater than the average dopant concentration of the semiconductor layer 134 and less than an order of magnitude higher than the average dopant concentration of the semiconductor layer 134. The carrier distribution layer 236 can have a peak dopant concentration that is in a range from 4×10¹⁶ atoms/cm³ to 8×10¹⁷ cm³. The peak dopant concentration for the carrier distribution layer 236 can be at an elevation that is 0.7 microns to 2.0 microns below the major surface 126. The carrier distribution layer 236 may extend to the major surface 126. In another implementation, the carrier distribution layer 236 may be spaced apart from the major surface 126. In such an implementation, a portion of the semiconductor layer 134 may overlap the carrier distribution layer 236. For either implementation, subsequent doping and patterning will be performed along the front side major surface 126.

In a particular implementation, the dopant concentration for the carrier distribution layer 236 may have a dopant concentration gradient where a dopant concentration of the carrier distribution layer 236 at a location closer to the carrier accumulation region 238 is greater than a dopant concentration of the carrier distribution layer 236 at a different location closer to semiconductor base material 132. The carrier distribution layer 236 can fully deplete during reverse bias under normal operating conditions.

Gap regions will be defined by portions of carrier distribution layer 236, the carrier accumulation region 238, and a subsequently-formed buried shield and allow majority carriers to flow along a path around the subsequently-formed buried shield and through the gap regions to the semiconductor layer 134. At least a portion of the carrier distribution layer 236 may underlap the carrier accumulation region 238. In another implementation, part or all of the carrier accumulation region 238 can overlap the carrier distribution layer 236. The carrier accumulation region 238 has the same conductivity type as the semiconductor layer 134. In an implementation, the carrier accumulation region 238 is n-type doped. In the implementation as illustrated in FIG. 2, the carrier accumulation region 238 includes a deep portion 2382 and a shallow portion 2384. The terms “deep” and “shallow” are used with respect to distance from the major surface 126 and not with respect to thickness (as measured in the Z-direction). As compared to each other, the shallow portion 2384 may have a thickness that is thicker, the same as, or thinner than the deep portion 2382.

In a finished device, the carrier accumulation region 238 can be at an elevation that is at least 0.3 microns below the major surface 126 and may be up to 1.5 microns below the major surface 126. The carrier accumulation region 238 can have a thickness (measured in the Z-direction) in a range from 0.2 micron to 0.5 micron. A thickness of the shallow portion 2384 can be in a range from 20% to 90% of a thickness of a combined thickness of the portions 2382 and 2384.

The deep portion 2382 can have a substantially uniform dopant concentration as a function of elevation from the major surface or may have a dopant concentration gradient where a dopant concentration of the deep portion 2382 at a location closer to a portion of the semiconductor layer 134 that overlaps the shallow portion 2384 is greater than a dopant concentration of the deep portion 2382 at a different location closer to the carrier distribution layer 236. The average dopant concentration of the deep portion 2382 can be 1.2 to 8 times higher than the average dopant concentration of the carrier distribution layer 236. The deep portion 2382 can have a peak dopant concentration that is in a range from 1×10¹⁷ atoms/cm³ to 2×10¹⁸ atoms/cm³.

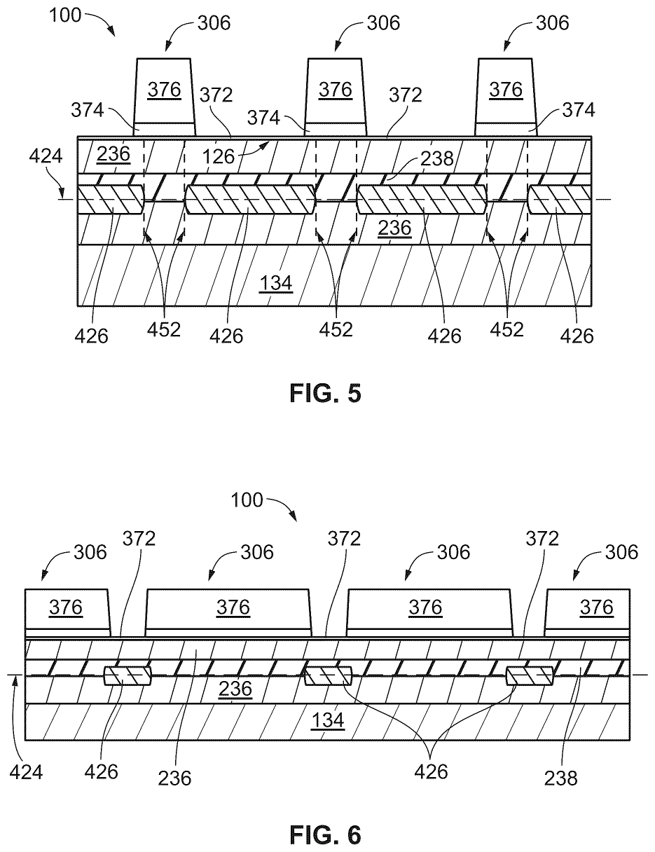

When the power transistor is on, the shallow portion 2384 helps to collect electrons from the source regions so that the electrons flow more readily to gap regions (addressed with respect to FIG. 5) as compared to the shallow portion 2384 not being present. The peak dopant concentration within the shallow portion 2384 is greater than the peak dopant concentration of each of the carrier distribution layer 236 and the deep portion 2382. In an implementation, the peak dopant concentration in the shallow portion 2384 is in a range from 2×10¹⁷ atoms/cm³ to 4×10¹⁸ atoms/cm³. In the same or different implementation, the peak dopant concentration of the shallow portion 2384 is in a range from 0.2 micron to 0.7 micron from the major surface 126.

Like the deep portion 2382, the shallow portion 2384 can fully deplete during reverse bias under normal operating conditions. In an implementation, the carrier accumulation region 238 can fully deplete when any or all of gap regions 452 are not fully depleted. The dopant concentration for the shallow portion 2384 can be higher than the dopant concentration of the deep portion 2382 because of the two-sided depletion from the body region and the buried shield described in more detail below.

In an alternative implementation, the shallow portion 2384 can be eliminated and the dopant concentration of the deep portion 2382 can be increased. This alternative implementation may eliminate one ion implantation operation but may also result in a higher on-state resistance, a lower breakdown voltage, or both, for the device, depending upon the amount with which the dopant concentration of the deep portion 2382 is increased with respect to an implementation that includes the shallow portion 2384.

If needed or desired, one or more thin layers may be formed in addition to the carrier distribution layer 236 and the carrier accumulation region 238 to provide a more gradual dopant concentration gradient between the semiconductor layer 134 and a subsequently-formed body region. The carrier accumulation region 238 can fully deplete during reverse bias under normal operating conditions. Its dopant concentration can be higher than the dopant concentration of the carrier distribution layer 236 because its closer proximity to the subsequently-formed body region aids in the depletion of this layer under reverse bias conditions.

### Design 1: Link Regions Adjacent to Body Contact Regions and Gap-Centered Link Regions

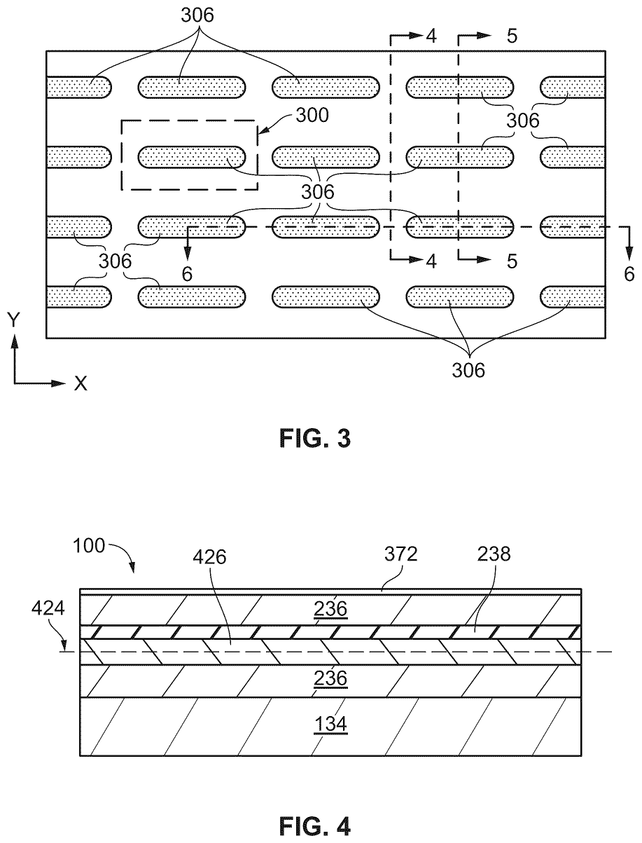

FIG. 3 includes a top view of a buried shield hard mask that includes mask members 306. The mask members 306 correspond to locations where gap regions will be formed. In the finished power transistor structures, electrons can flow through the gap regions when the power transistor is on. In this specification, some masks will be described as hard masks, such as the buried shield mask here. Other masks will be described as photoresist masks. In a hard mask, a pattern is first defined in photoresist and then transferred by etching to an underlying masking layer comprising either a single film or multiple films of oxide, nitride, polycrystalline silicon (polysilicon), or similar materials. This type of mask is referred to as a hard mask because it can withstand higher processing temperatures than photoresist, which is often needed when performing ion implantation into SiC. The need for high temperature ion implantation (for example, higher than room temperature, or 20° C. to 25° C.) increases with both the energy and dose of the implanted species. Depending upon the implant conditions, both photoresist masks and hard masks can sometimes be used interchangeably. Accordingly, the use of either a photoresist mask or a hard mask in this specification is for illustrative purposes only and should not be construed as a limitation on the invention.

In FIG. 3, not all the mask members 306 are identified with reference numbers to simplify understanding of the mask design. The power transistor that is being formed includes many unit cells, where one of the units cells 300 is identified in FIG. 3. Many other unit cells are present but not identified in FIG. 3. The unit cells that are immediately adjacent to the right, left, above and below the unit cell 300 are mirror images of the unit cell 300. Locations not covered by the mask members 306 will be implanted to form a buried shield.

FIGS. 4 to 6 include cross-sectional views of a portion of a workpiece 100 that includes the substrate 120 after the buried shield 426 is formed. FIG. 4 is along the sectioning line 4-4 in FIG. 3, FIG. 5 is along the sectioning line 5-5 in FIG. 3, and FIG. 6 is along the sectioning line 6-6 in FIG. 3.

Referring to FIGS. 3 to 6, the buried shield mask can include a relatively thinner oxide layer 372, a polysilicon layer 374, and a relatively thicker oxide layer 376. Of the three layers, a buried shield 426 is closest to the relatively thinner oxide layer 372 and farthest from the relatively thicker oxide layer 376. The relatively thinner oxide layer 372 can have a thickness in range from 10 nm to 90 nm. In the same or different implementation, the polysilicon layer 374 can have a thickness in a range from 30 nm to 300 nm. In the same or a further different implementation, the relatively thicker oxide layer 376 can have a thickness in a range from 0.9 micron to 4.0 microns. The polysilicon layer 374 and the relatively thicker oxide layer 376 can be patterned to form the mask members 306, and the relatively thinner oxide layer 372 can remain unpatterned during implantation. The relatively thinner oxide layer 372 can help to reduce the likelihood of implant channeling within the monocrystalline SiC when doping to form the buried shield 426. Also, for SiC, higher dose implants can be performed at elevated temperatures to reduce implant damage. The hard mask can allow a temperature for the ion implantation that conventional photoresist materials may not withstand.

The buried shield 426 helps to shield subsequently-formed gate electrodes from the drain voltage of the power transistor and can be used to limit or reduce the saturation current of the power transistor during a short-circuit event. The ability to survive short-circuit events on the order of several microseconds can be important for some applications such as motor drives and traction inverters. Limiting this current during a short-circuit event can extend the survival time for the power transistor.

A mid-elevation line 424 is where half of a thickness of the buried shield 426 is above the mid-elevation line, and another half of the thickness of buried shield 426 is below the mid-elevation line 424. As illustrated in FIG. 4, the mid-elevation line 424 is halfway between (1) the interface of the buried shield 426 and a portion of the carrier accumulation region 238 that overlaps the upper boundary of the buried shield 426 and (2) the interface of the buried shield 426 and a portion of the carrier distribution layer 236 that underlaps the lower boundary of the buried shield 426. Charge carriers flow through the gap regions 452 when the power transistor is turned on.

Some of the dopant for the buried shield 426 may extend under the edge of the buried shield hard mask due to scattering because of the energy(ies) of the implant(s). In an implementation, all of the buried shield 426 overlaps a portion of the carrier distribution layer 236; however, the buried shield 426 does not overlap all of the carrier distribution layer 236. In the same or different implementation, for the array of transistor structures within the power transistor, the buried shield 426 overlaps at least 10% of the carrier distribution layer 236 that lies below the mid-elevation line 424. As the amount of overlap increases, the ability to survive a short-circuit event improves. Thus, the overlap can be at least 40% or at least 70%. When the overlap becomes too great, R_{SP} may become higher than desired. In the same or different implementation, the buried shield 426 overlaps at most 99%, at most 98%, or at most 95% of the carrier distribution layer 236 that lies below the mid-elevation line 424. In any of the preceding or different implementations, the buried shield 426 overlaps in a range of 70% to 95% of the carrier distribution layer 236 that lies below the mid-elevation line 424.

The buried shield 426 has the opposite conductivity type as compared to the semiconductor layer 134. In an implementation, the buried shield 426 can be p-type doped. The buried shield 426 has a dopant concentration sufficient to counter dope portions of the carrier distribution layer 236 and the carrier accumulation region 238. The peak dopant concentration of the buried shield 426 can be the same or different from the peak dopant concentration of a subsequently-formed body region. In the same or different implementation, a peak dopant concentration of the buried shield 426 can be in a range from 8×10¹⁷ atoms/cm³ to 2×10¹⁹ atoms/cm³. In the same or a further implementation, the peak dopant concentration for the buried shield 426 can be at an elevation in a range from 0.3 microns to 0.9 microns below the major surface 126. Each of the gap regions 452 can have a narrowest width that is in a range from 0.4 micron to 3.0 microns.

The buried shield 426 may not fully deplete during reverse bias under normal operating conditions. However, unlike the subsequently-formed body region which can influence the threshold voltage of a subsequently formed transistor, fewer electrical characteristics of the power transistor may depend upon the buried shield 426. Therefore, the buried shield 426 can have a higher dopant concentration than the subsequently-formed body region, even beyond the 2×10¹⁹ atoms/cm³ limit recited above. Concentrations above this limit may be possible but may not significantly improve the drain voltage shielding properties of the buried shield 426.

In the same or different implementation, the carrier accumulation region 238 can extend across all of the lengths (X-direction) and widths (Y-direction) of the gap regions 452. In another implementation, the carrier accumulation region 238 may be formed so that it does not extend into the gap regions 452. Such a design (not illustrated) may be useful to reduce capacitive coupling between the gap regions 452 and when subsequently-formed gate electrodes overlap the gap regions 452.

The mask members 306 can be removed after the buried shield 426 is formed. The relatively thinner oxide layer 372 may or may not be removed at this point in the process.

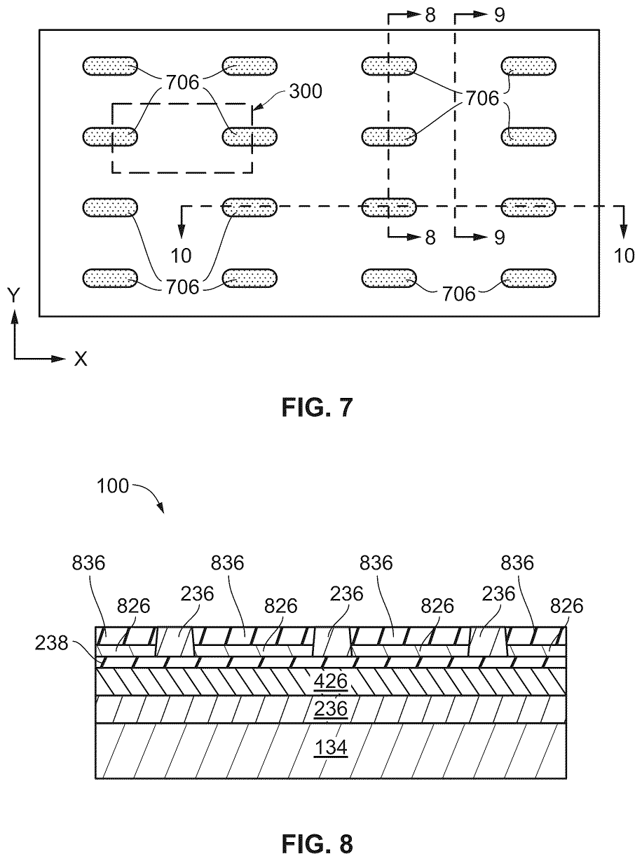

FIG. 7 includes a top view of a body/source mask that includes mask members 706. In FIG. 7, not all mask members 706 are identified with reference numbers to simplify understanding of the mask design. The mask members 706 can have the same or a different composition as previously described with respect to the buried shield mask. In an implementation, the body/source mask can be made from an oxide layer similar to the relatively thicker oxide layer 376 previously described, and thus, the relatively thinner oxide layer 372, the polysilicon layer 374, or both may or may not be present. Dopants for body region and source region will be implanted into the workpiece except where the mask members 706 are present.

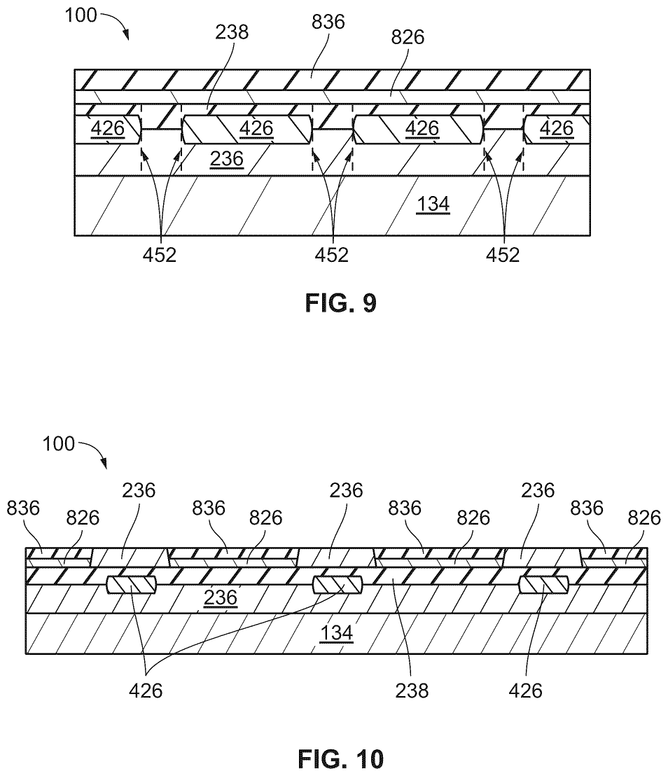

FIGS. 8 to 10 include cross-sectional views of the workpiece 100 after body region 826 and the source region 836 are formed and the body/source mask is removed. FIG. 8 is along the sectioning line 8-8 in FIG. 7, FIG. 9 is along the sectioning line 9-9 in FIG. 7, and FIG. 10 is along the sectioning line 10-10 in FIG. 7. The source region 836 overlaps the body region 826.

The body region 826 includes channel regions for transistor structures of the power transistor. The body region 826 has a conductivity type that is opposite any one or more of the semiconductor layer 134, the carrier distribution layer 236, or the carrier accumulation region 238. The buried shield 426 is spaced apart from the body region 826 by at least a portion of the carrier accumulation region 238. In an implementation, the body region 826 can be p-type doped. A peak dopant concentration of the body region 826 is greater than the average dopant concentration of the semiconductor layer 134, the carrier distribution layer 236, or both. In an implementation, the peak dopant concentration is in a range from 8×10¹⁷ atoms/cm³ to 8×10¹⁸ atoms/cm³. A peak dopant concentration for the body region 826 can be at an elevation that is in a range from 0.1 microns to 0.6 microns below the major surface 126. Unlike the carrier distribution layer 236 and the carrier accumulation region 238, the body region 826 may not fully deplete during reverse bias under normal operating conditions. These depletion conditions for the carrier distribution layer 236 and the carrier accumulation region 238 can be used to determine their maximum dopant concentrations for a given device geometry, and the depletion condition for the body region 826 can be used to determine a lower value for the dopant concentration for a given device geometry.

The source region 836 can have the same conductivity type as the carrier accumulation region 238, the gap regions 452, and the carrier distribution layer 236. In an implementation, the source region 836 can be n-type doped. The source region 836 can have a peak dopant concentration of at least 5×10¹⁸ atoms/cm³. In an implementation, the source region 836 can have a peak dopant concentration of at least 1×10¹⁹ atoms/cm³ to ensure a better ohmic contact to a subsequently-formed source terminal. In the same or different implementation, the peak dopant concentration may be at most 5×10²⁰ atoms/cm³, so that subsequently-formed body contact regions can be formed and counter dope portions of the source region 836. In the same or a different implementation, the source region 836 can extend from the major surface 126 to a depth in a range from 0.1 micron to 0.4 micron.

The body/source mask can be removed after doping for the body region 826 and the source region 836 is completed.

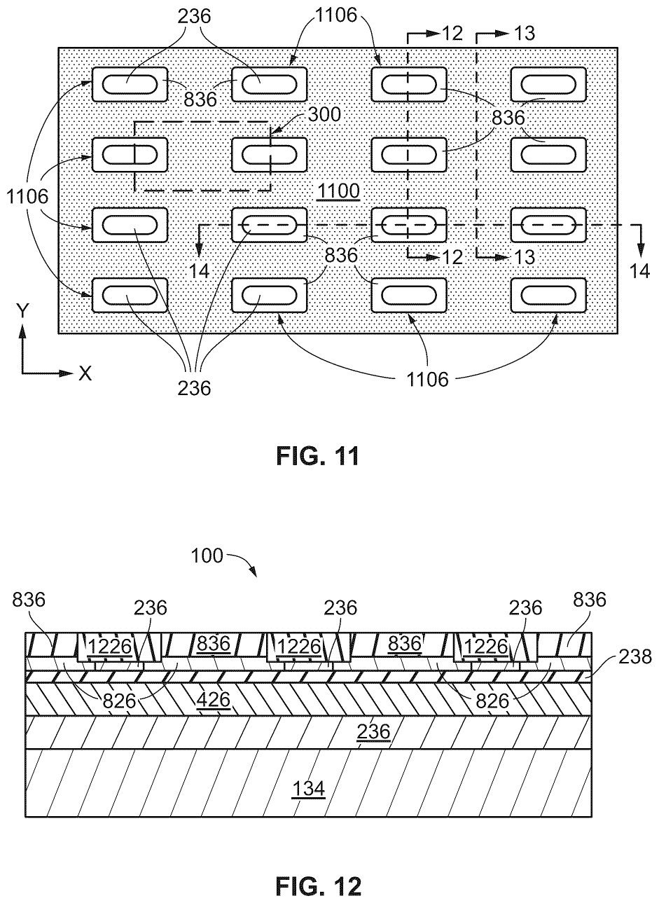

FIG. 11 includes a top view of a body contact mask 1100. The body contact mask 1100 can be formed and define body contact openings 1106 that overlap portions of the source region 836. In FIG. 11, not all the body contact openings 1106, portions of the source region 836 and carrier distribution layer 236 are identified with reference numbers to simplify understanding of the mask design.

The portions of the carrier distribution layer 236 correspond to locations that were covered by mask members 706 in FIG. 7 and did not receive doping when the body region 826 and source region 836 were formed. The body contact mask 1100 can have the same or a different composition as previously described with respect to the buried shield mask. In an implementation, the body contact mask 1100 can be made from an oxide layer similar to the relatively thicker oxide layer 376 previously described, and thus, the relatively thinner oxide layer 372, the polysilicon layer 374, or both may or may not be present. In a further implementation, the body contact mask 1100 can be made of photoresist.

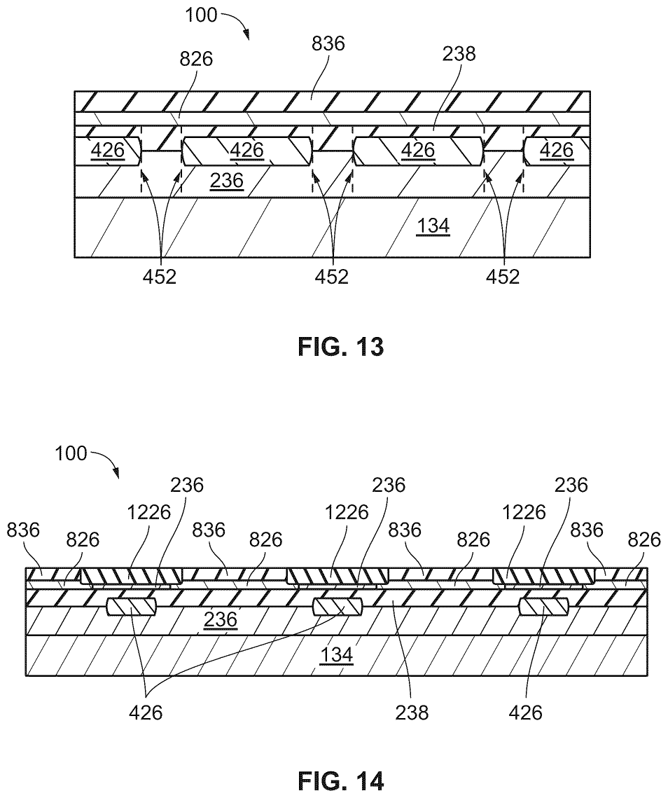

FIGS. 12 to 14 include cross-sectional views of the workpiece 100 after body contact regions 1226 are formed and the body contact mask 1100 is removed. FIG. 12 is along the sectioning line 12-12 in FIG. 11, FIG. 13 is along the sectioning line 13-13 in FIG. 11, and FIG. 14 is along the sectioning line 14-14 in FIG. 11.

The body contact regions 1226 can be electrically coupled to the body region 826, and in a particular implementation, can be electrically connected to a subsequently-formed source terminal. The body contact regions 1226 are formed by doping portions of the carrier accumulation region 238 and the source region 836 at locations below the body contact openings 1106. The body contact regions 1226 have the same conductivity type as the body region 826 and the buried shield 426. In an implementation, the body contact regions 1226 are p-type doped.

The body contact regions 1226 extend through the source region 836 and to any depth within the body region 826. In an implementation, the body contact regions 1226 do not extend to the buried shield 426. In the same or a further different implementation, the body contact regions 1226 extend from the major surface 126 to a depth in a range from 0.3 micron to 0.7 micron. In a particular implementation, the body contact regions 1226 have a peak dopant concentration that is greater than the peak dopant concentration of the source region 836. In the same or different implementation, the body contact regions 1226 have a peak dopant concentration of at least 1×10¹⁹ atoms/cm³ and may have a peak dopant concentration that is at most 2×10²¹ atoms/cm³.

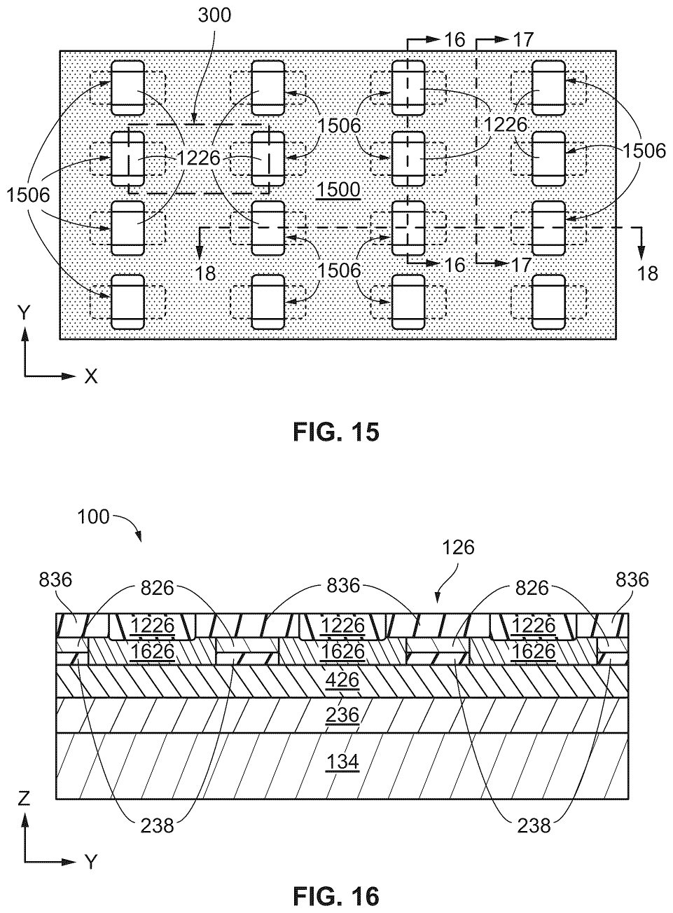

FIG. 15 includes a top view of a link mask 1500. The link mask 1500 can be formed and define link openings 1506 where dopant for link regions will be introduced into the workpiece. In FIG. 15, not all the link openings 1506 and body contact regions 1226 are identified with reference numbers to simplify understanding of the mask design.

Referring to the top view in FIG. 15, within the link openings 1506, portions of the body contact regions 1226 underlap the centers of the link openings 1506. Other portions of the body contact regions 1226, illustrated with dashed lines, extend in the X-direction outside the link openings 1506, and the link mask 1500 overlaps such other portions of the body contact regions 1226. Portions of the source region 836 (not labelled in FIG. 15) underlap the link openings 1506 at locations that are closer to the top and bottom of each of the link openings 1506 in FIG. 15. The link mask 1500 can have the same or a different composition as previously described with respect to the buried shield mask. In an implementation, the link mask 1500 can be made from an oxide layer similar to the relatively thicker oxide layer 376 previously described, and thus, the relatively thinner oxide layer 372, the polysilicon layer 374, or both may or may not be present.

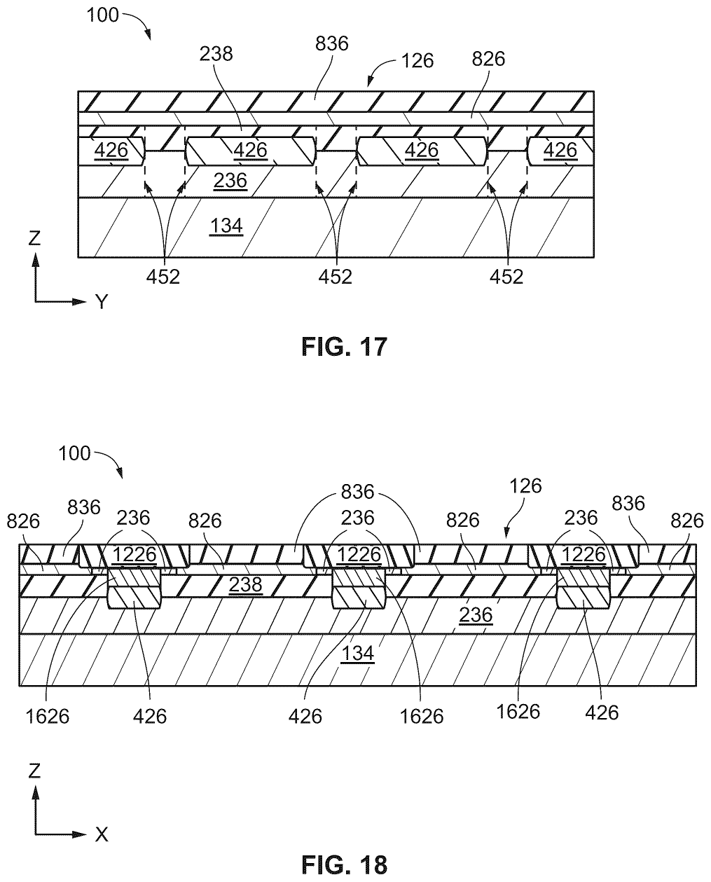

FIGS. 16 to 18 include cross-sectional views of the workpiece 100 after link regions 1626 are formed and the link mask 1500 is removed. FIG. 16 is along the sectioning line 16-16 in FIG. 15, FIG. 17 is along the sectioning line 17-17 in FIG. 15, and FIG. 18 is along the sectioning line 18-18 in FIG. 15.

The link regions 1626 electrically couple the buried shield 426 and the body contact regions 1226 to one another. In an implementation, the link regions 1626 electrically connect the buried shield 426 and the body contact regions 1226 to one another. In the same or different implementation, the link regions 1626 contact the buried shield 426 and the body contact regions 1226. Hence the design can be considered a body contact adjacent design.

The link regions 1626 have the same conductivity type as the buried shield 426 and the body contact regions 1226. In an implementation, the links regions 1626 are p-type doped. Each of the link regions 1626 has a corresponding body contact region 1226 that overlaps the particular link region 1626.

From a top view, the link regions 1626 underlap the body contact regions 1226 and extend into the gap regions 452. The center of any particular link regions 1626, the center of its corresponding body contact region 1226, and the center of the width (as measured in the Y-direction) of its corresponding gap region 452 lie substantially along an axis in the Z-direction. Hence, the design can be referred to as a gap-centered design for the link regions 1626.

The link regions 1626 underlap portions of the body contact regions 1226 and the source region 836 and extend through the portions of the gap regions 452 and the carrier accumulation region 238 and to any depth within the buried shield 426. In an implementation, the link regions 1626 can be at a depth in a range from 0.4 micron to 0.9 micron from the major surface 126.

The link regions 1626 have a peak dopant concentration that is greater than the peak dopant concentrations of the gap regions 452 and the carrier accumulation region 238 and may or may not have a peak dopant concentration that is less than the peak dopant concentration of either or both of the source region 836 and the buried shield 426. In the same or different implementation, the peak dopant concentration of the link regions 1626 can be less than the peak dopant concentration of the body contact regions 1226. In the same or a further different implementation, the link regions 1626 have a peak dopant concentration in a range from 1×10¹⁷ atoms/cm³ to 1×10¹⁹ atoms/cm³.

An anneal can be performed to activate dopants with respect to the previously described doping operations. Before performing the anneal, a graphite capping layer can be formed over the workpiece to protect the SiC surface from sublimation, pitting and other forms of surface roughening during the anneal. In an implementation, the graphite capping layer can have a thickness in a range from 1.5 microns to 5.0 microns. The capping layer can be deposited in the form of photoresist and decomposed to a layer primarily composed of carbon during the subsequent anneal. The anneal can be performed for a soak time in a range from 10 minutes to 60 minutes at a temperature in a range from 1500° C. to 1800° C. The dopants within the workpiece may not significantly diffuse during the anneal, and thus, the doped layers and doped regions substantially may retain their shapes and locations as originally formed. In an implementation, the anneal can be performed in an inert ambient.

The anneal can be performed before or after forming gate trenches as described below. The anneal can be performed before forming a gate dielectric layer because a material within the gate dielectric layer may not be able to withstand the temperature used for the anneal. After reading this specification, skilled artisans will be able to determine where in the process flow the anneal is performed.

Many doping operations have been described previously. The order of performing the doping operations after forming the semiconductor layer 134 can be changed. For example, doping for the body contact regions 1226 could be performed before many of the other doping operations previously described, such as doping for the carrier distribution layer 236, the carrier accumulation region 238, the body region 826, and the source region 836. Thus, before any anneal is performed, the doping operations can be performed in many different orders. In another implementation, another anneal may be performed after some but not all doping operations. Any doping operations performed before the other anneal is performed may not be performed after the other anneal, and any doping operations after the other anneal is performed may not be performed before the other anneal.

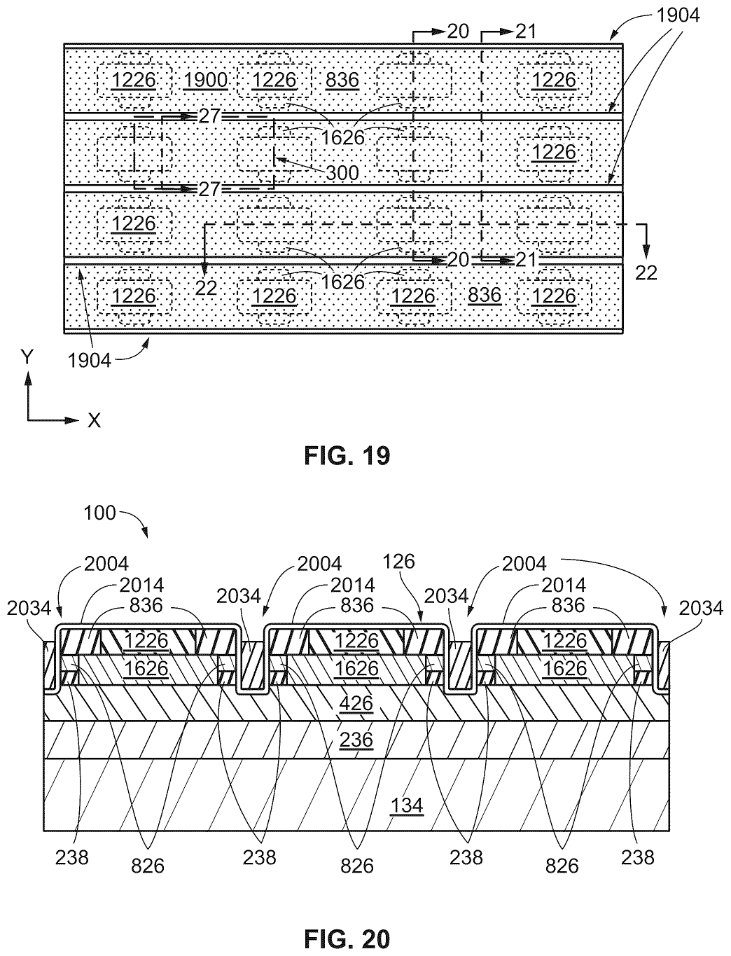

FIG. 19 includes a top view of a gate trench mask 1900 over the workpiece 100. The gate trench mask 1900 defines gate trench openings 1904 that are used to define gate trenches. The gate trench openings 1904 can be in the form of stripes that have lengths that are in the X-direction. The gate trench mask 1900 can have the same or a different composition as previously described with respect to the buried shield mask. In an implementation, the gate trench mask 1900 can be made from an oxide layer similar to the relatively thicker oxide layer 376 previously described, and thus, the relatively thinner oxide layer 372, the polysilicon layer 374, or both may or may not be present. In another implementation, the gate trench mask 1900 can be made of photoresist.

Some features are illustrated in FIG. 19 to assist in understanding the layout. The gate trench mask 1900 overlaps the body contact regions 1226 and the link regions 1626. The body contact regions 1226 and the link regions 1626 are illustrated with dashed lines. Some, but not all, body contact regions 1226 and some, but not all, link regions 1626 are labelled in FIG. 19.

The body contact regions 1226 can lie at the major surface 126 (labelled in FIGS. 16 to 18) and have substantially rectangular shapes as illustrated in FIG. 19. The body contact regions 1226 have lengths that extend in the X-direction in FIG. 19. The source region 836 is at locations along the major surface 126 that are outside of the body contact regions 1226. The link regions 1626 are farther into the workpiece 100 and spaced apart from the major surface 126. The link regions 1626 have substantially rectangular shapes and lengths that extend in the Y-direction in FIG. 19. Most of the body contact regions 1226 and portions of the source region 836 overlap the link regions 1626.

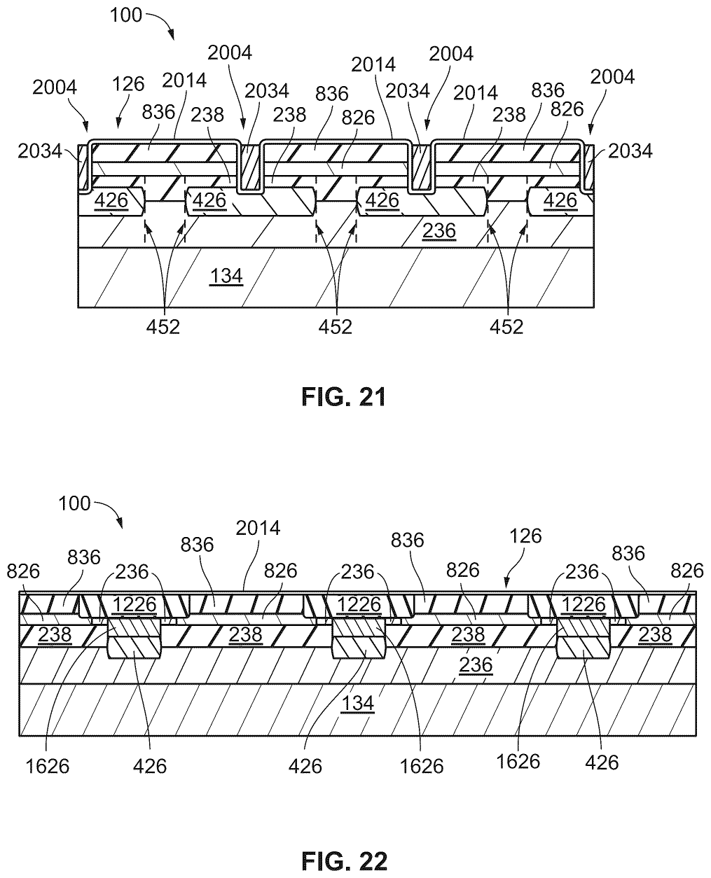

FIGS. 20 to 22 include cross-sectional views of the workpiece 100 after defining gate trenches 2004, removing the gate trench mask 1900, forming a gate dielectric layer 2014 and gate electrodes 2034, and recessing the gate electrodes 2034 within the gate trenches 2004. FIG. 20 is along the sectioning line 20-20 in FIG. 19, FIG. 21 is along the sectioning line 21-21 in FIG. 19, and FIG. 22 is along the sectioning line 22-22 in FIG. 19.

The semiconductor material below the gate trench openings 1904 of the gate trench mask 1900 is etched to define the gate trenches 2004. Referring to FIGS. 20 and 21, the gate trenches 2004 extend from the major surface 126 through the source region 836 and the body region 826 and to at least the carrier accumulation region 238. The gate trenches 2004 may contact the carrier accumulation region 238. In an implementation, the bottoms of the gate trenches 2004 may be at an elevation as deep as 0.05 micron from the top of the carrier accumulation region 238. In another implementation, the gate trenches 2004 can extend through the carrier accumulation region 238 and into the buried shield 426.

In the same or different implementation, the gate trenches 2004 do not extend completely through the buried shield 426. In the same or a more particular implementation, the gate trenches 2004 are spaced apart from and do not physically contact (1) a portion of the carrier distribution layer 236 beneath the buried shield 426, (2) the underlying semiconductor layer 134 or both (1) and (2). In any of the implementations, the depths of the gate trenches 2004 can be in a range from 0.3 micron to 1.1 microns.

Widths of the gate trenches 2004 correspond to the widths of the gate trench openings 1904 that are measured in the Y-direction in FIG. 19. The widths of the gate trenches 2004 can be the same or different from one another. In an implementation, the widths of the gate trenches 2004 can be in a range from 0.1 micron to 0.9 microns. The gate trench mask 1900 can be removed after the gate trenches 2004 are defined.

If the previously described anneal was not performed before defining the gate trenches 2004, the anneal can be performed after defining the gate trenches 2004. The anneal can be performed before forming the gate dielectric layer 2014. When the anneal is performed after defining the gate trenches 2004, the graphite capping layer may fill or at least partially fill the gate trenches 2004.

As illustrated in FIGS. 19, 20, and 22, the link regions 1626 are spaced apart from and do not physically contact the gate trenches 2004. In other designs addressed later in this specification, link regions can physically contact and may optionally be centered with respect to gate trenches.

A gate dielectric layer 2014 can be formed along exposed surfaces of the workpiece 100, including sidewalls and bottoms of the gate trenches 2004 and over portions of the source region 836 and the body contact regions 1226 that are along the major surface 126. In an implementation, the gate dielectric layer 2014 is spaced apart from and does not physically contact the gap regions 452. The electrical field across the gate dielectric layer 2014 is substantially lower than it would be if any of the gate trenches 2004 exposed a portion of the gap regions 452. Thus, the gate dielectric layer 2014 may be less susceptible to long term reliability issues. The gate dielectric layer 2014 can include an oxide or an oxynitride. In an implementation, the gate dielectric layer 2014 can have a thickness in a range from 20 nm to 150 nm.

After formation of the gate dielectric layer 2014, a gate conductive layer can be deposited over the gate dielectric layer 2014. The gate conductive layer can include a single film or a plurality of films, where the single film or any of the films within the plurality of films can include a doped semiconductor layer, an elemental metal (a metal that is not part of an alloy and not part of a compound, such as W, Cu, Al, etc.), a metal alloy (for example, TiW, Al-1 wt % Cu, or the like), or a conductive metal compound (for example, a conductive metal silicide or a conductive metal nitride). The gate conductive layer can have a thickness sufficient to fill the gate trenches 2004. In a particular implementation, the gate conductive layer can be n-type doped polysilicon.

An etch can be performed to remove portions of the gate conductive layer that overlie portions of the source region 836 and the body contact regions 1226 outside the gate trenches to form gate electrodes 2034. The etch can be performed as a timed etch or with endpoint detection and an overetch. Endpoint detection can occur when the gate dielectric layer 2014 is exposed. The overetch can be performed to recess portions of the gate electrodes 2034 within the gate trenches 2004 to reduce gate-to-source capacitance (C_{GS}). The elevation along the upper surfaces of the recessed portions of the gate electrodes are no lower than the lowermost points of the source region 836 along their corresponding gate trenches 2004. In another implementation, relatively higher C_{GS} may be acceptable, and the gate electrodes 2034 may not be recessed within the gate trenches 2004.

As illustrated in FIGS. 20 and 21, the gate dielectric layer 2014 is located between the gate electrodes 2034 and sidewalls and bottoms of the gate trenches 2004. If needed or desired, a silicide process can be performed to silicide exposed surfaces of the gate electrodes 2034 when the gate electrodes 2034 include doped polysilicon.

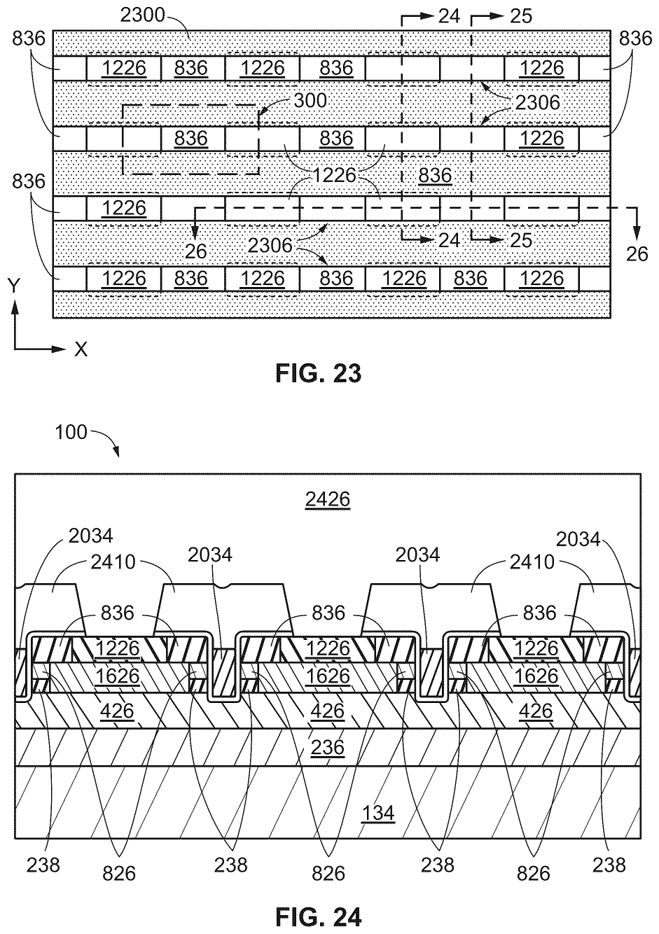

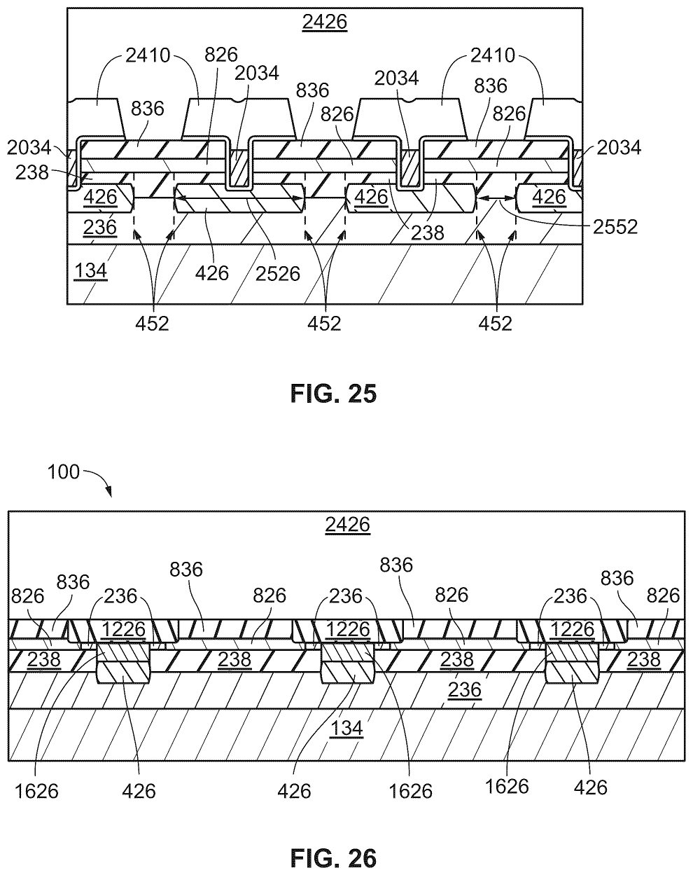

Referring to FIGS. 23 to 26, an interlevel dielectric (ILD) layer 2410 can be formed over the workpiece 100, a contact mask 2300 can be formed over the ILD layer 2410 and include contact openings 2306 to expose portions of the ILD layer 2410. The exposed portions of the ILD layer 2410 are etched to expose portions of the source region 836 and the body contact regions 1226. The contact mask 2300 is removed, and a source terminal 2426 can be formed over transistor structures within the power transistor. FIG. 24 is along the sectioning line 24-24 in FIG. 23, FIG. 25 is along the sectioning line 25-25 in FIG. 23, and FIG. 26 is along the sectioning line 26-26 in FIG. 23.

The ILD layer 2410 can include a single film or a plurality of films. The single film or any one or more of the films of the within the plurality of films can include an oxide, a nitride, or an oxynitride. The single film or any one or more of the films of the within the plurality of films may or may not be doped with boron, phosphorus, or the like. The ILD layer 2410 can be deposited to a thickness in a range from 0.5 micron to 3.0 microns. A planarization process can be performed so that the uppermost surface of the ILD layer 2410 lies along a plane. The planarization process can be performed using chemical mechanical polishing or a resist etch-back process.

The contact mask 2300 defines the contact openings 2306 that expose portions of the ILD layer 2410. In an implementation, the contact mask 2300 can be made of photoresist.

In an implementation, the contact openings 2306 are spaced apart from the gate electrodes 2034. The contact mask 2300 can include other openings that expose portions of the gate electrodes 2034 (not illustrated in FIG. 23), wherein such openings are located along the workpiece 100 at locations outside of the views as illustrated in FIGS. 23 to 26. The ILD layer 2410 is etched to expose portions of the source region 836, the body contact regions 1226, and the gate electrodes 2034. The contact mask 2300 is removed after the etch is performed. In FIG. 23, some, and not all, of the body contact regions 1226 and portions of the source region 836 are labeled.

A conductive layer is deposited over the ILD layer 2410 and within contact openings extending through the ILD layer to contact the source region 836, the body contact regions 1226, and the gate electrodes 2034. The conductive layer can include one or more films, wherein each film includes a conductive material. In an implementation, the conductive material can include a doped semiconductor material, an elemental metal (a metal that is not part of a compound or an alloy), a metal alloy, or a conductive metallic compound. A non-limiting example of a conductive material can be doped polysilicon (n-type or p-type), W, WN, Ti, Ta, TiW, Al-1 wt % Cu, Ni, Cu, Au, Pt, a conductive metal nitride (e.g., WN, TiN, TaN, etc.), a conductive metal silicide (TiSi₂, CoSi₂, PtSi, etc.), or the like. In an implementation, the conductive layer can be deposited to a thickness in a range from 0.7 micron to 5.0 microns.

A photoresist mask is formed over the conductive layer and patterned to form a source terminal 2426 in FIGS. 24 to 26 and a gate terminal (not illustrated). The source terminal 2426 physically contacts the source region 836 and body contact regions 1226. In an implementation, ohmic contacts are formed between the source terminal 2426 and the source region 836 and the body contact regions 1226. The gate terminal can physically contact the gate electrodes 2034.

If needed or desired, a passivation layer (not illustrated) can be formed over the ILD layer 2410, the source terminal 2426, and the gate terminal. The passivation layer can include one or more films of a insulating material. In a particular implementation, the passivation layer includes polyimide that is coated and patterned to expose portions of the source terminal 2426 and the gate terminal. The reverse side of the workpiece may be provided with a metal layer that is a drain terminal and physically contacts the semiconductor base material 132.

In FIG. 25, the widths of portions of buried shields between immediately adjacent gap regions can be the widest widths of the portions and are illustrated by a dimension 2526. The dimension 2552 corresponds to the narrowest widths of each gap region 452. The buried shield-to-gap ratio is the ratio of the dimension 2526 to the dimension 2552. The significance of the buried shield-to-gap ratio is addressed later in this specification.

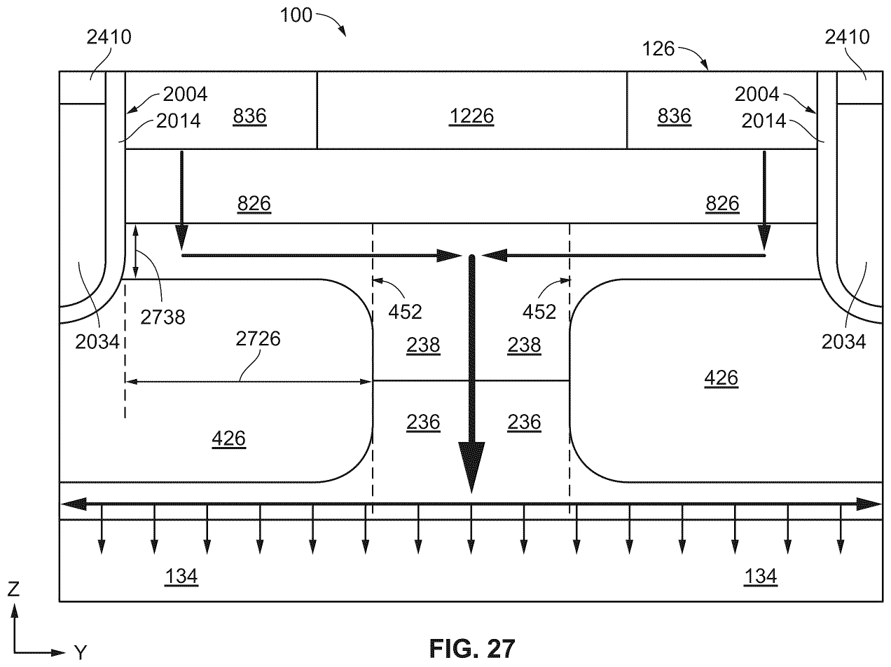

FIG. 27 includes a cross-sectional view along sectioning line 27-27 in FIG. 19 and includes a portion of the unit cell 300 to illustrate the majority carrier flow within the transistor structures. Portions of the workpiece above the major surface 126 are removed to improve understanding of features of the power transistor. The cross-sectional view in FIG. 27 is through the unit cell 300 along a line in the Y-direction that intersects source region 836 and body contact region 1226 but does not intersect link region 1626. The majority carrier flow is illustrated with the arrows. Majority carriers are electrons for an n-channel transistor and holes for a p-channel transistor.

In a finished device and when the power transistor is in an on-state, majority carriers flow along paths from the source region 836, through channel regions that are portions of the body region 826 that are adjacent to the sidewalls of the gate trenches 2004, into the carrier accumulation region 238, into the carrier distribution layer 236 via the gap region 452, through the semiconductor layer 134, through the semiconductor base material 132 (not illustrated in FIG. 27), and into a drain terminal (not illustrated) for the power transistor.

The majority carriers flow substantially vertically (in the Z-direction) through the channel region and are illustrated in FIG. 27 with arrows extending through the body region 826 and into the carrier accumulation region 238. After entering the carrier accumulation region 238, the majority carriers flow substantially laterally (in the Y-direction) between the body region 826 and the buried shield 426 and are illustrated in FIG. 27 with arrows within the carrier accumulation region 238. Although FIG. 27 includes arrows illustrated in the Y-direction passing through the center of carrier accumulation region 238, the majority carriers are not restricted to flow only along the center of the carrier accumulation region 238. At least some of the majority carriers can flow through the carrier accumulation region 238 at locations other than in the center of the carrier accumulation region 238.

The majority carriers enter the gap region 452, which is illustrated between the dashed lines immediately adjacent to portions of the buried shield 426. The majority carriers enter the gap region 452 and then flow substantially vertically (in the Z-direction) through gap region 452 and enter the carrier distribution layer 236. Although FIG. 27 includes a single arrow illustrated in the Z-direction passing through the center of gap region 452, the majority carriers are not restricted to flow only along the center of the gap region 452. At least some of the majority carriers can flow through the gap region 452 at locations other than in the center of the gap region 452.

The carrier distribution layer 236 helps to distribute more uniformly the majority carriers into semiconductor layer 134 as compared to transistor structures where the carrier distribution layer 236 would have been restricted only to the gap region 452 or where the carrier distribution layer 236 is replaced by the semiconductor layer 134 (the semiconductor layer 134 would have extended into the gap region 452 and physically contacted the carrier accumulation region 238).

After entering the carrier distribution layer 236, at least some of the majority carriers can flow substantially laterally (in the Y-direction) under the buried shield 426 and are illustrated in FIG. 27 with a double-headed arrow extending within the carrier distribution layer 236. The majority carriers can then flow from the carrier distribution layer 236 into the semiconductor layer 134 and are illustrated with the vertical arrows (in the Z-direction) extending from the double-headed arrow within the carrier distribution layer 236 to the semiconductor layer 134. Although FIG. 27 includes the double-headed arrow illustrated in the Y-direction passing through the center of carrier distribution layer 236, the majority carriers are not restricted to flow in the Y-direction only along the center of the carrier distribution layer 236. At least some of the majority carriers can flow through the carrier distribution layer 236 at locations other than in the center of the carrier distribution layer 236. The majority carriers can continue flowing in a substantially vertical direction within the semiconductor layer 134 and the semiconductor base material 132 (not illustrated in FIG. 27). Referring to FIG. 27, the majority carrier flow from the carrier distribution layer 236 into the semiconductor layer 134 is illustrated with relatively thinner arrows in the Z-direction.

Dimensions 2726 and 2738 are illustrated in FIG. 27. The dimension 2726 is a distance between a first point and a second point and is in a lateral direction (Y-direction). The first point is within the buried shield 426 and underlaps an intersection of the body region 826, the carrier accumulation region 238, and the gate trench 2004. The second point is where the buried shield 426 within the transistor structure extends farthest toward the gap region 452. Referring to FIG. 27, the first point corresponds to the left-hand arrow of the dimension 2726, and the second point corresponds to the right-hand arrow of the dimension 2726.

A dimension 2738 is a distance between the body region 826 and the buried shield 426 along the gate trench 2004 in a direction perpendicular to the major surface 126 (the Z-direction in FIG. 27). The dimension 2738 corresponds generally to the thickness of the carrier accumulation region 238 adjacent to the gate trench 2004. An aspect ratio is a ratio of the dimension 2726 to the dimension 2738.

As the aspect ratio, the buried shield-to-gap ratio, or both increases, the saturation current is reduced and allows for a longer time that the power transistor can withstand a short-circuit event. The improvement in short-circuit withstand time (desired) occurs with an increase in the R_{SP} (undesired). Thus, as the aspect ratio, the buried shield-to-gap ratio, or both increases, the short-circuit withstand time and the specific on-state resistance increase, and as the aspect ratio, the buried shield-to-gap ratio, or both decreases, the short-circuit withstand time and the specific on-state resistance decrease.

The aspect ratio can be at least 1.5:1. In a conventional design, the aspect ratio is less than 1.2:1 and many times is no greater than 1.0:1. In an implementation, the aspect ratio can be at most 50:1. In a particular implementation, the aspect ratio can be at most 9.0:1 so that specific on-state resistance is not too high. In any of the preceding or different implementations, the aspect ratio is in a range from 2.0:1 to 5.0:1. After reading this specification, skilled artisans will be able to determine the aspect ratio that provides a good balance between short-circuit withstand time and specific on-state resistance.

The buried shield-to-gap ratio can be at least 2.0:1. In a conventional design, the buried shield-to-gap ratio is less than 1.8:1 and many times is no greater than 1.2:1. In an implementation, the buried shield-to-gap ratio can be at most 50:1. In a particular implementation, the buried shield-to-gap ratio can be at most 12:1 so that the specific on-state resistance is not too high. In any of the preceding or different implementations, the buried shield-to-gap ratio is in a range from 3.0:1 to 6.0:1. After reading this specification, skilled artisans will be able to determine the buried shield-to-gap ratio that provides a good balance between short-circuit withstand time and specific on-state resistance.

### Design 2: Link Regions Staggered From Body Contact Regions and Gap-Centered Link Regions

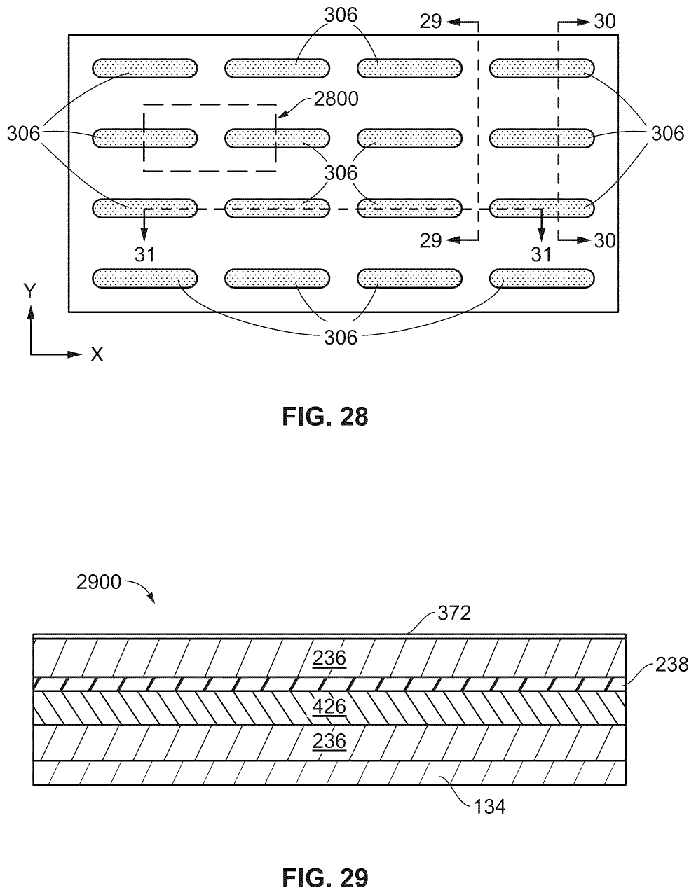

The buried shield mask, the body/source mask, and the body contact mask for Design 2 are the same as the buried shield mask, the body/source mask, and the body contact mask, respectively, for Design 1 except that the locations of the mask members for the buried shield mask for Design 2 (see FIG. 28) are shifted by a half unit cell in the X-direction relative to the locations for the mask members of the buried shield mask for Design 1 (see FIG. 3). The gate trench mask and the contact mask are the same for Designs 1 to 4. The substrate 120 is processed as previously described and illustrated in FIGS. 1 and 2.

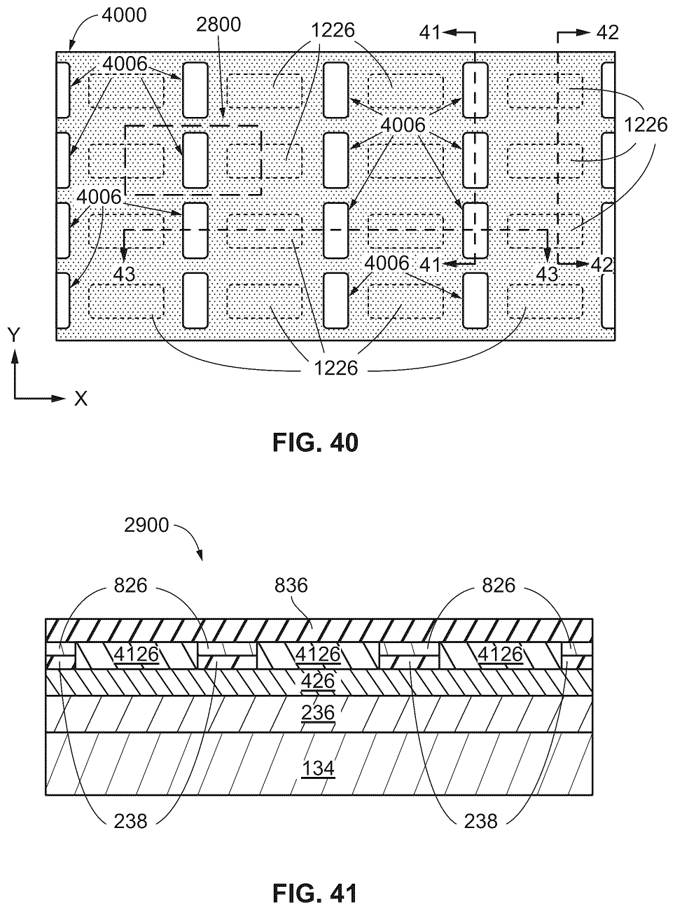

The buried shield mask including the mask members 306 in FIG. 28 are formed over the substrate 120. The locations of the mask members 306 in Design 2 are shifted by half of a unit cell in the X direction as compared to the locations of the mask members 306 in Design 1. This shift in the buried shield mask corresponds with a similar shift to a subsequently-formed link mask 4000 in FIG. 40. By applying a similar shift to these two masks, the relative position between the link regions and the gap regions in the buried shield remain the same.

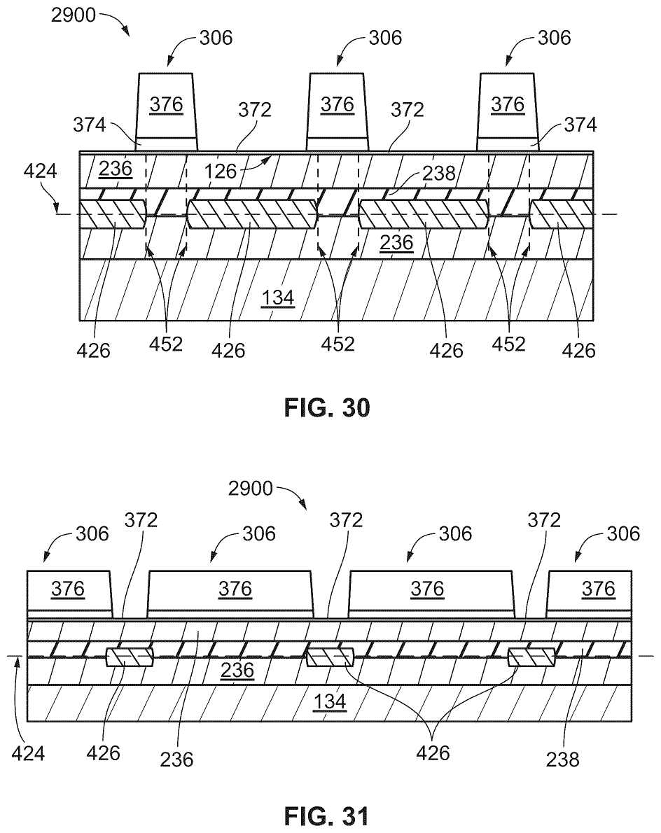

FIG. 28 includes a unit cell 2800. Many other unit cells are present but not identified in FIG. 28. The unit cells that are immediately adjacent to the right, left, above and below the unit cell 2800 are mirror images of the unit cell 2800. After the mask members 306 are formed, the buried shield 426 is formed, and the mask members 306 are removed after forming the buried shield 426. FIGS. 29 to 31 include cross-sectional views of a workpiece 2900 after the buried shield 426 is formed and after the mask members 306 are removed. FIG. 29 is along the sectioning line 29-29 in FIG. 28, FIG. 30 is along the sectioning line 30-30 in FIG. 28, and FIG. 31 is along the sectioning line 31-31 in FIG. 28.

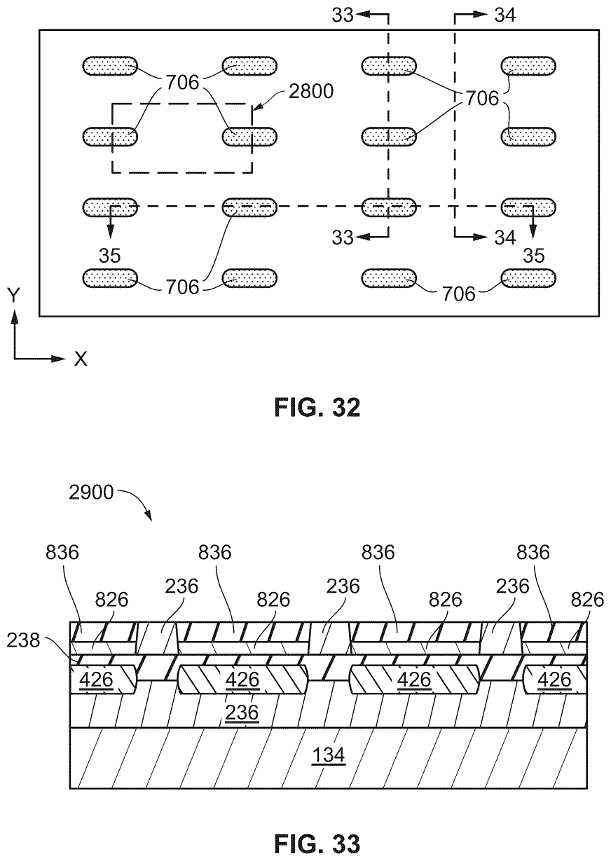

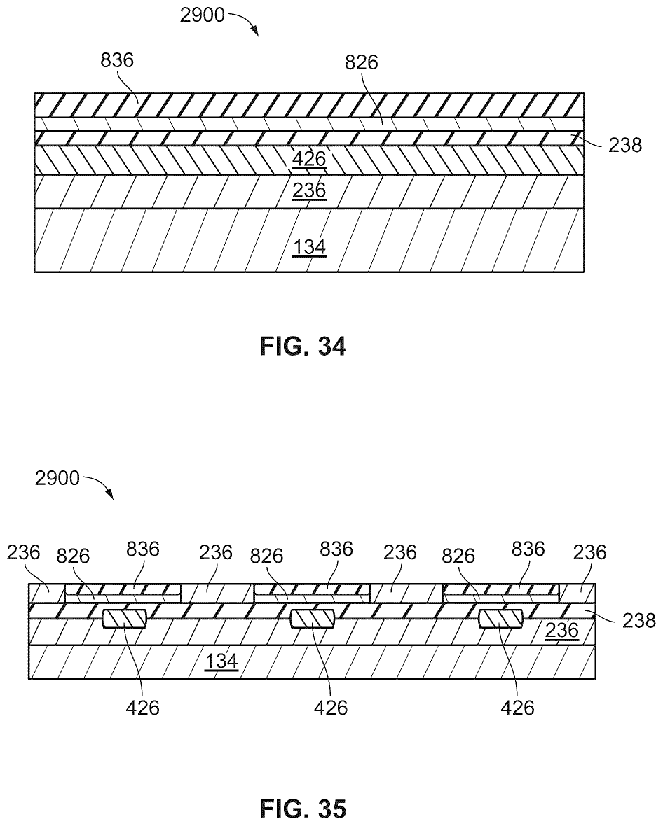

The body/source mask including the mask members 706 in FIG. 32 are formed over the workpiece 2900. The locations of the mask members 706 in Design 2 are unchanged as compared to the locations of the mask members 706 in Design 1. FIGS. 33 to 35 include cross-sectional views of the workpiece 2900 after the body region 826 and the source region 836 are formed and the mask members 706 are removed. FIG. 33 is along the sectioning line 33-33 in FIG. 32, FIG. 34 is along the sectioning line 34-34 in FIG. 32, and FIG. 35 is along the sectioning line 35-35 in FIG. 32. The locations of the body region 826 and the source region 836 in Design 2 are unchanged as compared to the locations of the body region 826 and the source region 836 in Design 1.

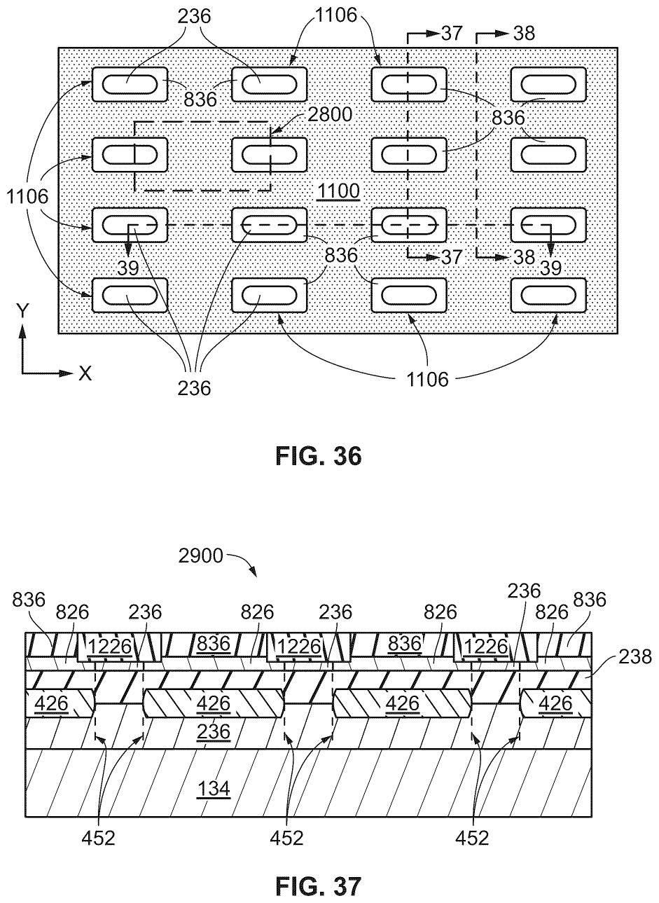

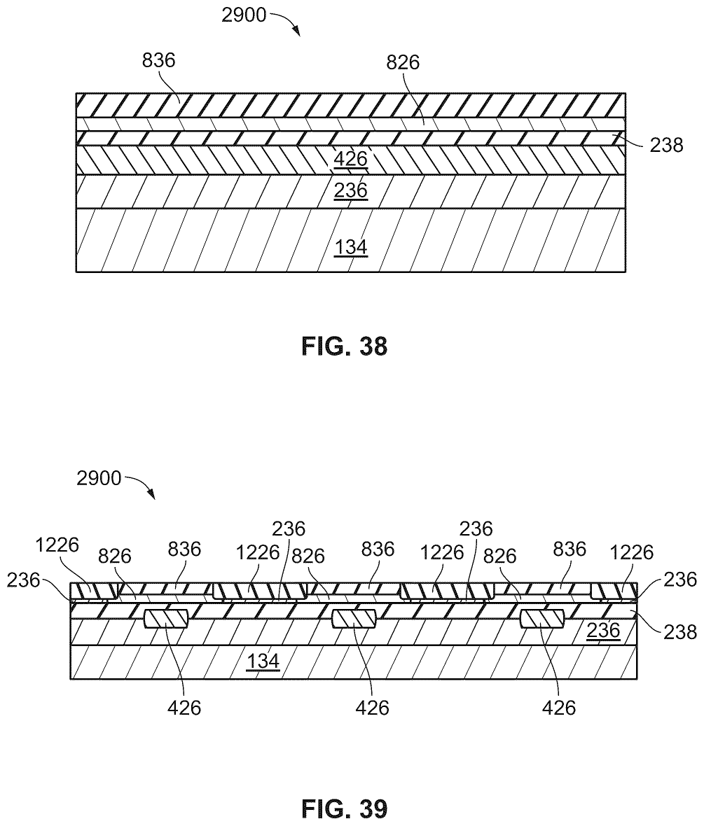

The body contact mask 1100 that defines the body contact openings 1106 is formed over the workpiece 2900 as illustrated in FIG. 36. The locations of the body contact openings 1106 in Design 2 are unchanged as compared to the locations of the body contact openings 1106 in Design 1. FIGS. 37 to 39 include cross-sectional views of the workpiece 2900 after the body contact regions 1226 are formed and the body contact mask 1100 is removed. FIG. 37 is along the sectioning line 37-37 in FIG. 36, FIG. 38 is along the sectioning line 38-38 in FIG. 36, and FIG. 39 is along the sectioning line 39-39 in FIG. 36. The locations of the body contact regions 1226 in Design 2 are unchanged as compared to the locations of the body contact regions 1226 in Design 1.

The location of the buried shield 426 in Design 2 is the same as the buried shield in Design 1 except that the location of the buried shield 426 in Design 2 is shifted by a half unit cell in the X-direction relative to the location of the buried shield 426 in Design 1. The relationships between the buried shield 426, the body region 826, the source region 836, and the body contact regions 1226 as described with respect to Design 1 also apply to the relationships between the buried shield 426, the body region 826, the source region 836, and the body contact regions 1226 in Design 2.

FIG. 40 includes a top view of a link mask 4000. The link mask 4000 can be formed and define link openings 4006 where dopant for link regions will be introduced into the workpiece. In FIG. 40, not all the link openings 4006, body contact regions 1226, and exposed portions of the source region 836 are identified with reference numbers to simplify understanding of the mask design.

Referring to the top view in FIG. 40, the locations of the link openings 4006 are shifted by half of a unit cell in the X-direction with respect to the locations of the body contact regions 1226 that are covered by the link mask 4000 and illustrated with dashed lines. Thus, portions of the source region 836 underlap the link openings 4006, and no portion of the body contact regions 1226 underlap the link openings 4006. In an implementation, the link openings 4006 are not concentric with the body contact regions 1226. In the same or different implementation, from the top view in FIG. 40, the link openings 4006 are half way between corresponding body contact regions 1226. The link mask 4000 can have any of the constructions and compositions as described with the link mask 1500 in Design 1.

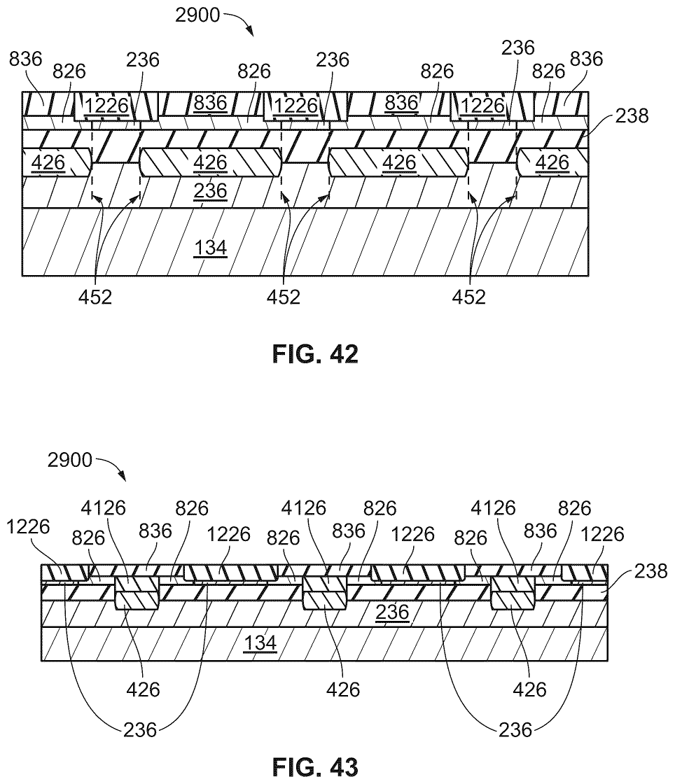

FIGS. 41 to 43 include cross-sectional views of the workpiece 2900 after link regions 4126 are formed below the link openings 4006 in the link mask 4000 and the link mask 4000 is removed. The link regions 4126 have the same conductivity type as the buried shield 426 and the body contact regions 1226. In an implementation, the links regions 4126 are p-type doped. The link regions 4126 can be at any depth and have any of the peak dopant concentrations as previously described with respect to the link regions 1626 for Design 1. FIG. 41 is along the sectioning line 41-41 in FIG. 40, FIG. 42 is along the sectioning line 42-42 in FIG. 40, and FIG. 43 is along the sectioning line 43-43 in FIG. 40.

The link regions 4126 electrically couple the buried shield 426 and the body contact regions 1226 to one another via portions of the body region 826. In an implementation, the link regions 4126 electrically connect the buried shield 426 and the body contact regions 1226 to one another via portions of the body region 826. In the same or different implementation, the link regions 4126 physically contact the buried shield 426 and the body region 826.

Each of the link regions 4126 has a corresponding portion of the buried shield 426 that underlaps the particular link region 4126. The link regions 4126 underlap the source region 836 and extend through the portions of the gap regions 452 and the carrier accumulation region 238 and to any depth within the buried shield 426. From a top view, the link regions 4126 lie at a lower elevation but do not underlap the body contact regions 1226. The center of any particular link region 4126, and the center of the width (as measured in the Y-direction) of its corresponding gap region 452 lie substantially along an axis in the Z-direction. Hence, the design can be referred to as a gap-centered design for the link regions 4126.

In the same or different implementation, from a top view, the locations of the link regions 4126 are shifted by half of a unit cell in the X-direction with respect to the locations of the body contact regions 1226. The link regions 4126 are spaced apart from and do not contact the body contact regions 1226. Hence, the design can be referred to as having link regions 4126 that are staggered with respect to the body contact regions 1226.

An anneal can be performed to activate dopants with respect to the previously described doping operations. The use of a graphite capping layer, soak time, temperature, and gas for the anneal can be any of those previously described with respect to the anneal in Design 1. The anneal can be performed before or after forming gate trenches as described below. The anneal can be performed before forming a gate dielectric layer because a material within the gate dielectric layer may not be able to withstand the temperature used for the anneal. The order of performing the doping operations can be of those previously described with respect to Design 1.

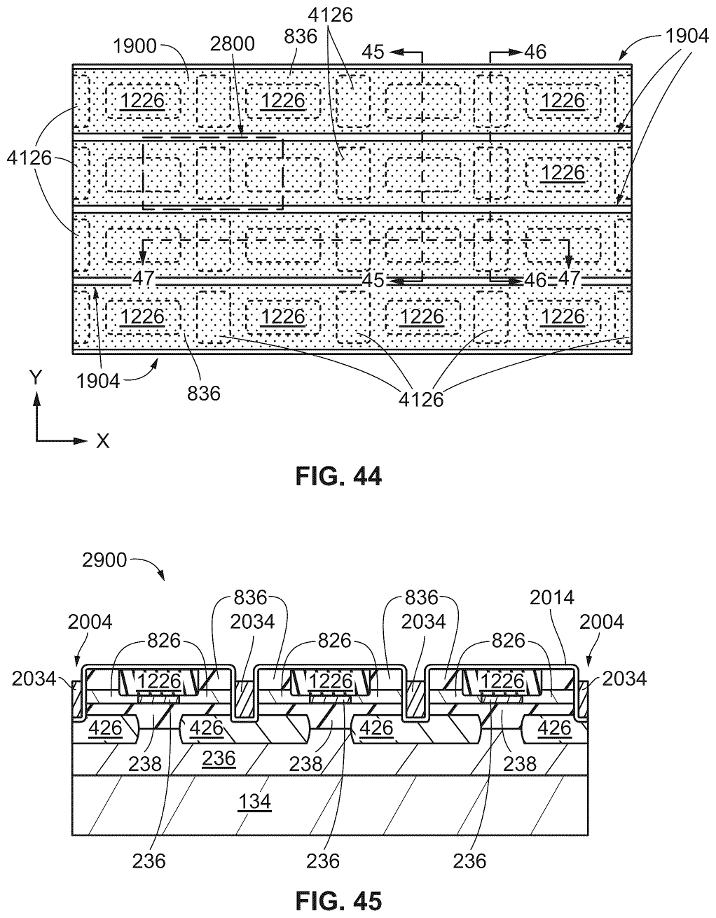

FIG. 44 includes a top view of the gate trench mask 1900 over the workpiece 2900. The gate trench mask 1900 defines gate trench openings 1904 that are used to define gate trenches. The gate trench openings 1904 can be in the shape of stripes that have lengths that extend in the X-direction. The gate trench mask 1900 can have any of the constructions and compositions as previously described with respect to the gate trench mask 1900 in Design 1.

Positional relationships between the gate trench openings 1904 and the buried shield 426, the body region 826, the source region 836, and the body contact regions 1226 are described with respect to Design 1.

The locations of the link regions 4126 are different as compared to the locations of the link regions 1626 in Design 1. The gate trench mask 1900 overlaps the link regions 4126 that are illustrated with dashed lines. Some, but not all, of the link regions 4126 are labelled in FIG. 44. The link regions 4126 are farther into the workpiece 2900 and spaced apart from the major surface 126. The link regions 4126 have substantially rectangular shapes and lengths that extend in the Y-direction in FIG. 44. The link regions 4126 are spaced apart from the gate trench openings 1904. Design 2 can help to reduce the risk of drain-to-source punchthrough. As an example, compare FIG. 18 with FIG. 43. In FIG. 18, the source region 836 is separated from the underlying carrier accumulation region 238 by the body region 826. When a reverse bias is applied between source and drain, the body region 826 is the only intervening p-type doped region preventing current from flowing between the source region 836 and the carrier accumulations region 238. Since other device electrical characteristics, such as threshold voltage, are dependent upon the doping concentration of the body region 826, there are limits to how high this concentration can be to prevent punchthrough. Compare now to the equivalent structure in FIG. 43. In addition to the body region 826, the buried shield 426 and the link regions 4126 also underlap source region 836. In an implementation, these p-type doped regions, specifically, the body region 826, the buried shield 426, and the link regions 4126, provide additional suppression against punchthrough.

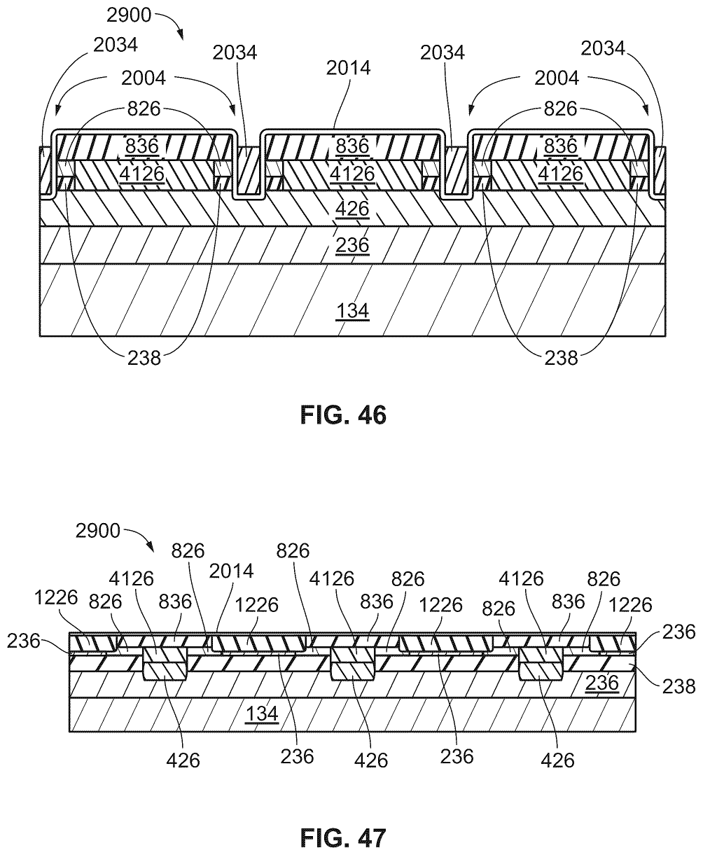

FIGS. 45 to 47 include cross-sectional views of the workpiece 2900 after defining gate trenches 2004, removing the gate trench mask 1900, forming a gate dielectric layer 2014 and gate electrodes 2034, and recessing the gate electrodes 2034 within the gate trenches 2004. FIG. 45 is along the sectioning line 45-45 in FIG. 44, FIG. 46 is along the sectioning line 46-46 in FIG. 44, and FIG. 47 is along the sectioning line 47-47 in FIG. 44. The positional relationships between any of the gate trenches 2004, the gate dielectric layer 2014, the gate electrodes 2034, and other doped regions and layers are addressed with respect to Design 1.

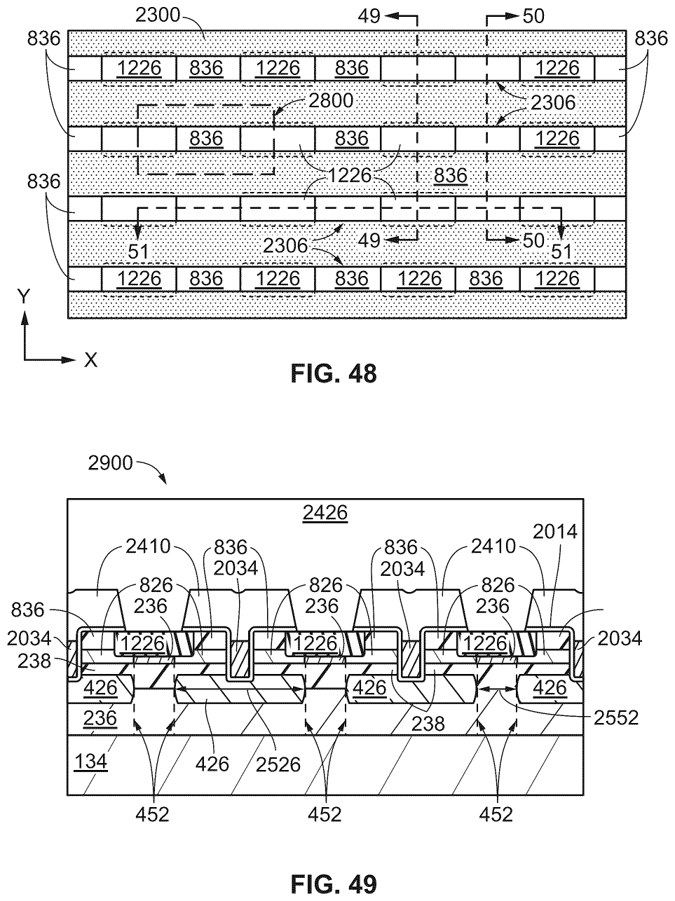

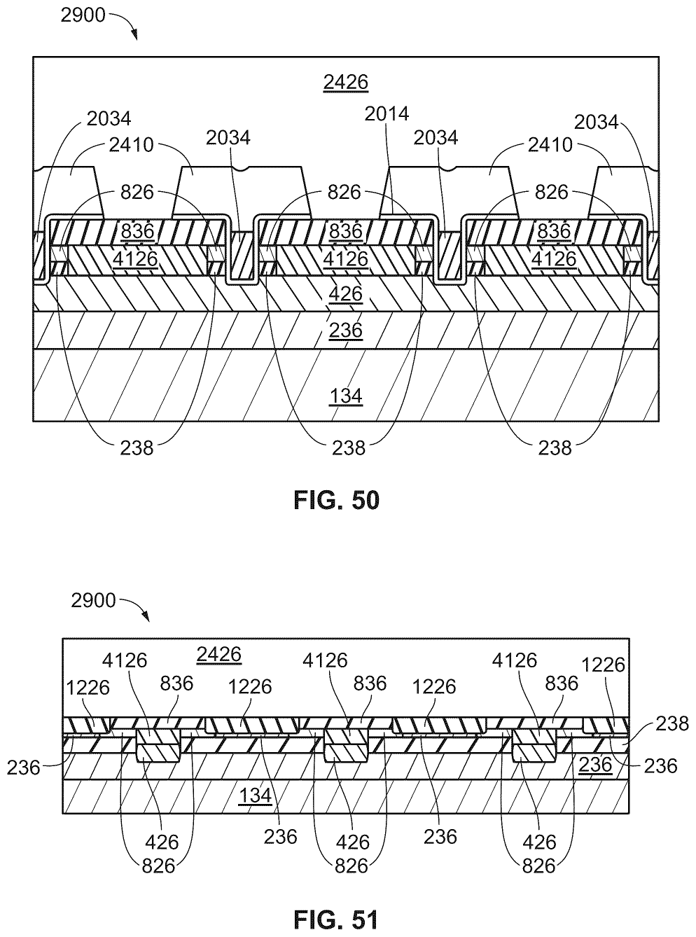

Referring to FIGS. 48 to 51, the ILD layer 2410 can be formed over the workpiece 2900, the contact mask 2300 can be formed over the ILD layer 2410 and includes the contact openings 2306 to expose portions of the ILD layer 2410. The contact mask 2300 can be removed after the ILD layer 2410 is patterned to define contact openings extending though the ILD layer 2410. The source terminal 2426 and a gate terminal (not illustrated) can be formed. FIG. 49 is along the sectioning line 49-49 in FIG. 48, FIG. 50 is along the sectioning line 50-50 in FIG. 48, and FIG. 51 is along the sectioning line 51-51 in FIG. 48.

If needed or desired, a passivation layer (not illustrated) can be formed over the ILD layer 2410, the source terminal 2426, and the gate terminal. The passivation layer can include any number of films and compositions as previously described with respect to the passivation layer for Design 1. The passivation layer can be patterned to expose portions of the source terminal 2426 and the gate terminal. The reverse side of the workpiece may be provided with a metal layer that is a drain terminal and physically contacts the semiconductor base material 132.

The transistor structures of the power transistor within the workpiece 2900 can have the same majority carrier flow characteristics, dimensions, and aspect and buried shield-to-gap ratios as illustrated in FIGS. 25 and 27 and described with respect the transistor structures of the power transistor within the workpiece 100.

### Design 3: Link Regions Adjacent to Body Contact Regions and Gate Trench-Centered Link Regions

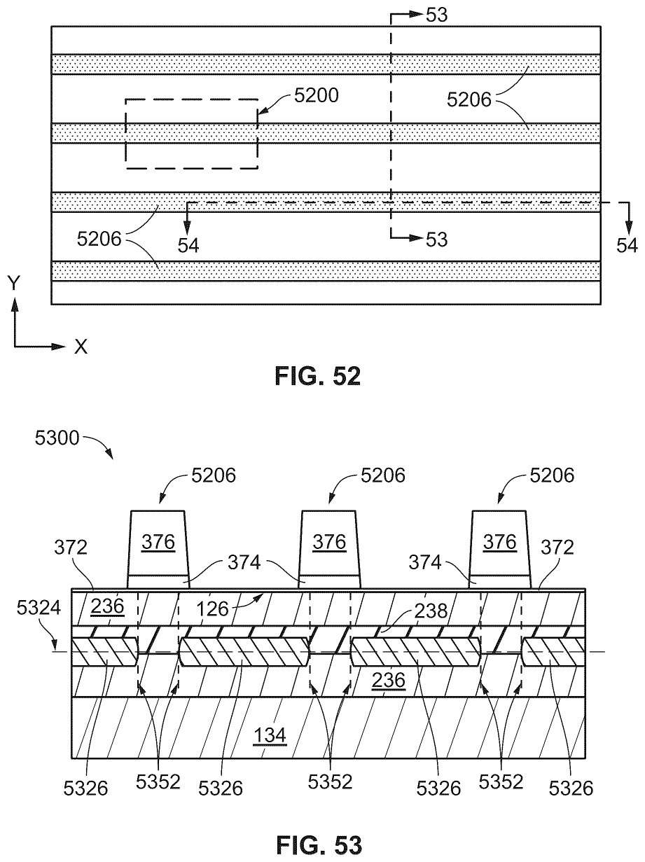

FIG. 52 includes a top view of a buried shield hard mask that includes mask members 5206. As illustrated in FIG. 52, the mask members 5206 are in the form of stripes. The mask members 5206 correspond to locations where gap regions will be formed. In the finished power transistor structures, electrons can flow through the gap regions when the power transistor is on.

The power transistor that is being formed includes many unit cells, where one of the units cells 5200 is identified in FIG. 52. Many other unit cells are present but not identified in FIG. 52. The unit cells that are immediately adjacent to the right, left, above and below the unit cell 5200 are mirror images of the unit cell 5200. Locations not covered by the mask members 5206 will be implanted to form buried shields.

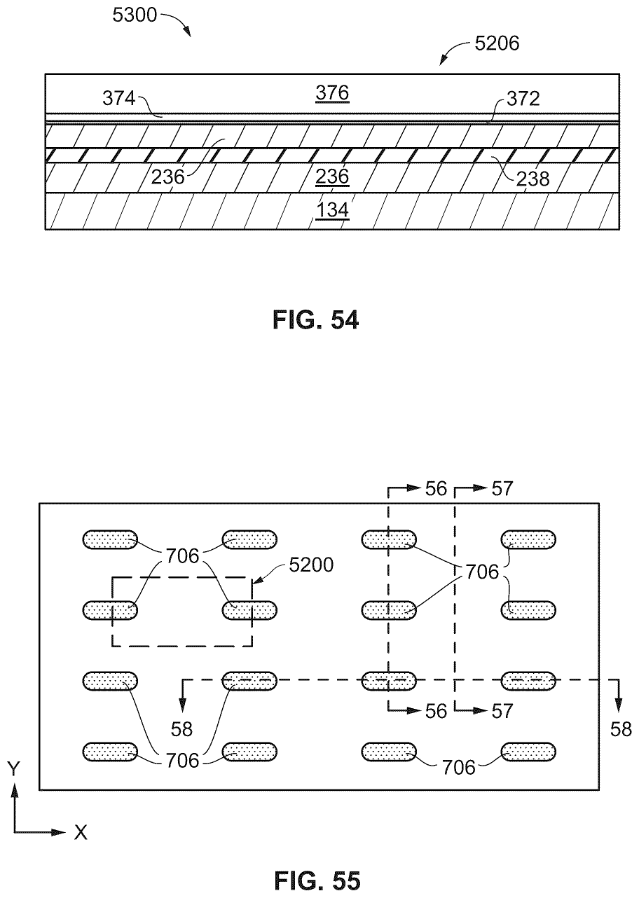

FIGS. 53 and 54 include cross-sectional views of the workpiece 5300 after the buried shields 5326 are formed. FIG. 53 is along the sectioning line 53-53 in FIG. 52, and FIG. 54 is along the sectioning line 54-54 in FIG. 52. Referring to FIGS. 52 to 54, the buried shield mask can include any of the constructions, compositions, and thicknesses as previously described with respect to the buried shield mask in Design 1.

The buried shields 5326 can serve any of the purposes, include any of the dopants and dopant concentrations, use implant energies, depths of the peak dopant concentrations, lie at elevations, and have widths as previously described with respect to the buried shield 426 in Design 1. The mid-elevation line 5324 is at the same elevation with respect to the buried shields 5326 as the mid-elevation line 424 with respect to the buried shield 426 in Design 1.

For the array of transistor structures within the power transistor, the buried shields 5326 overlap at least 10% of the carrier distribution layer 236 that lies below the mid-elevation line 5324. As the amount of overlap increases, the ability to survive a short-circuit event improves. Thus, the overlap can be at least 40% or at least 70%. When the overlap becomes too great, R_{SP} may become higher than desired. In the same or different implementation, the buried shields 5326 overlap at most 99%, at most 98%, or at most 95% of the carrier distribution layer 236 that lies below the mid-elevation line 5324. In any of the precedent or different implementation, the buried shields 5326 overlap in a range of 70% to 95% of the carrier distribution layer 236 that lies below the mid-elevation line 5324.

In the same or different implementation, the carrier accumulation region 238 can extend across all of the lengths (X-direction) and widths (Y-direction) of the gap regions 5352. In another implementation, the carrier accumulation region 238 may be formed so that it does not extend into the gap regions 5352. Such a design may be useful to reduce capacitive coupling between the gap regions 5352 and subsequently-formed gate electrodes that overlap the gap regions 5352. In the same or different implementation, the carrier accumulation region 238 can fully deplete when any or all of the gap regions 452 are not fully depleted.

The mask members 5206 can be removed after the buried shields 5326 are formed. The relatively thinner oxide layer 372 may or may not be removed at this point in the process.

The body/source mask and the body contact mask for Design 3 are the same as the buried shield mask, the body/source mask, and the body contact mask, respectively, for Design 1. The substrate 120 is processed as previously described and illustrated in FIGS. 1 and 2.

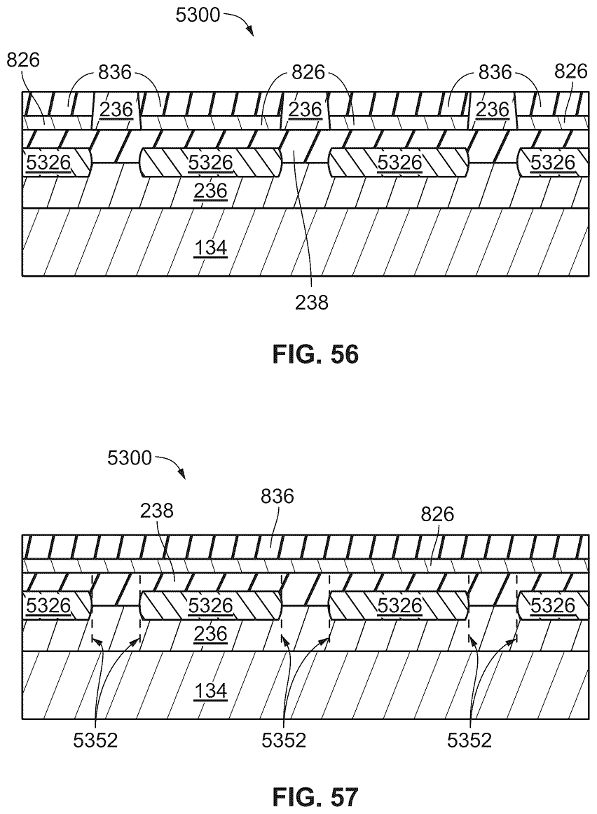

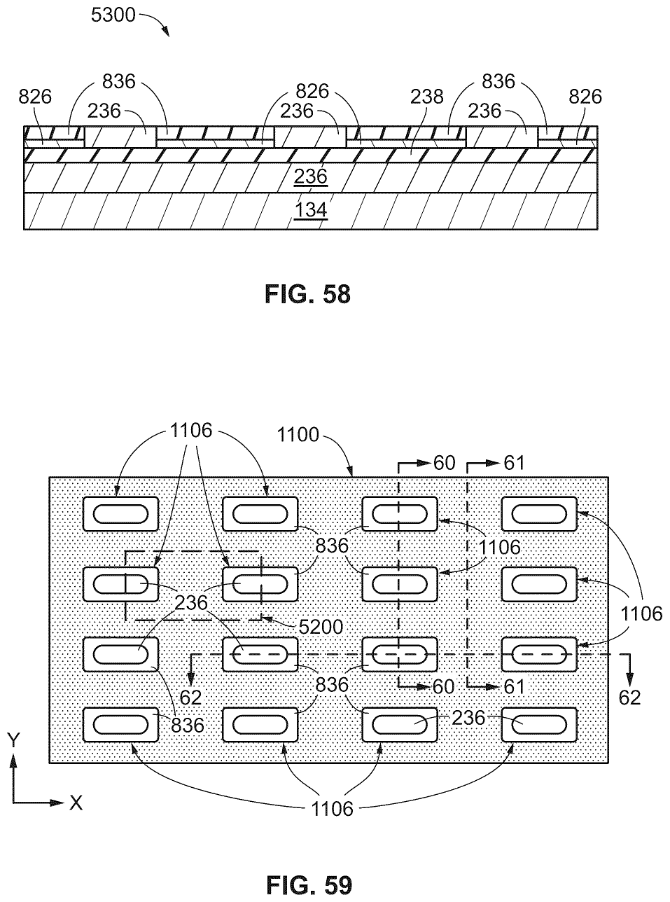

The body/source mask including the mask members 706 in FIG. 55 are formed over the workpiece 5300. FIGS. 56 to 58 include cross-sectional views of the workpiece 5300 after the body region 826 and the source region 836 are formed and the mask members 706 are removed. FIG. 56 is along the sectioning line 56-56 in FIG. 55, FIG. 57 is along the sectioning line 57-57 in FIG. 55, and FIG. 58 is along the sectioning line 58-58 in FIG. 55.

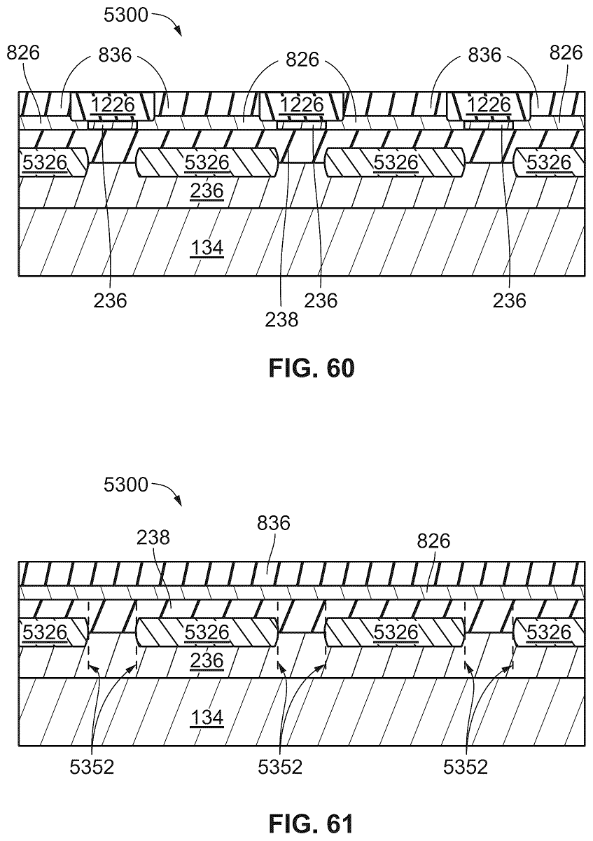

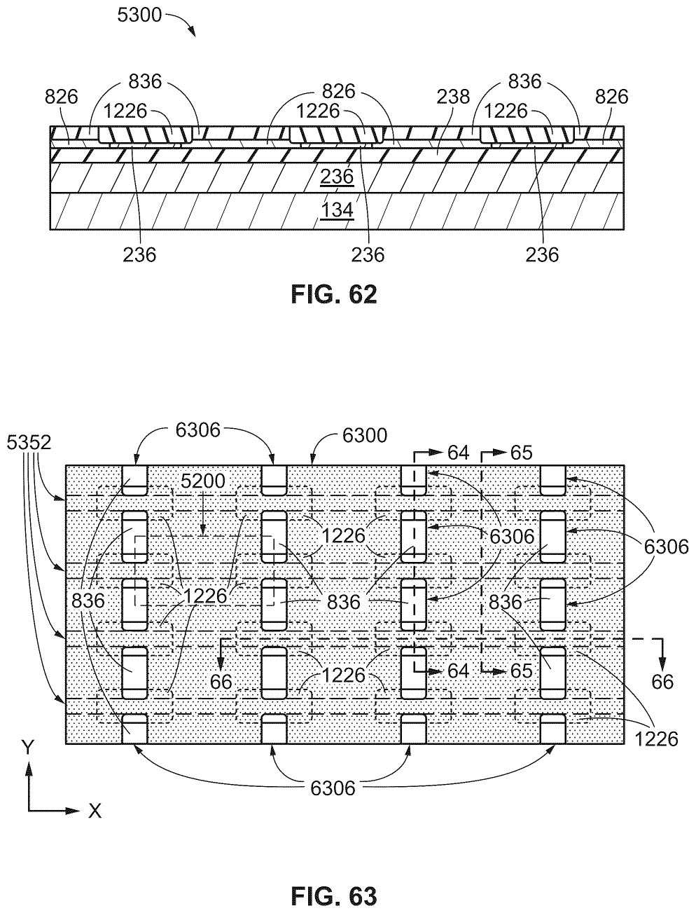

The body contact mask 1100 that defines the body contact openings 1106 is formed over the workpiece 5300 as illustrated in FIG. 59. FIGS. 60 to 62 include cross-sectional views of the workpiece 5300 after the body contact regions 1226 are formed and the body contact mask 1100 is removed. FIG. 60 is along the sectioning line 60-60 in FIG. 59, FIG. 61 is along the sectioning line 61-61 in FIG. 59, and FIG. 62 is along the sectioning line 62-62 in FIG. 59.

The body region 826, the source region 836, and the body contact regions 1226 in Design 3 are the same as the body region 826, the source region 836, and the body contact regions 1226, respectively, in Design 1 except that the buried shields 5326 and the gaps regions 5352 in Design 3 are in the shapes of stripes. The relationships between the buried shield 426, the body region 826, the source region 836, and the body contact regions 1226 as described with respect to Design 1 also apply to the relationships between the buried shields 5326, the body region 826, the source region 836, and the body contact regions 1226 in Design 3.

FIG. 63 includes a top view of a link mask 6300. The link mask 6300 can be formed and define link openings 6306 where dopant for link regions will be introduced into the workpiece. In FIG. 63, not all the link openings 6306, body contact regions 1226, and exposed portions of the source region 836 identified with reference numbers to simplify understanding of the mask design. The link mask 6300 can have any of the constructions and compositions as previously described with respect to the link mask 1500.

As compared to the link openings 1506 in Design 1, the link openings 6306 in Design 3 are shifted by a half unit cell in the Y-direction in FIG. 63. The link openings 6306 overlap portions of the body contact regions 1226 and the source region 836; however, the centers of the link openings 6306 do not overlap the centers of the body contact regions 1226. In the same or different implementation, from the top view in FIG. 63, each of centers of the link openings 6306 can be half way between centers of corresponding pairs body contact regions 1226 that lie closer to the top and bottom of FIG. 63. The link mask 6300 can have any of the constructions and compositions as described with the link mask 1500 in Design 1.

The gap regions 5352 in FIG. 63 (illustrated with dashed lines) correspond to where the mask members 5206 of the buried shield mask were located. Thus, the gap regions 5352 were not doped when forming the buried shields 5326. In this particular implementation, the link openings 6306 are aligned to edges of the gap regions 5352 as illustrated in FIG. 63. In other implementations, the link openings 6306 may extend slightly over the gap regions 5352 or may not extend completely to the gap regions 5352.

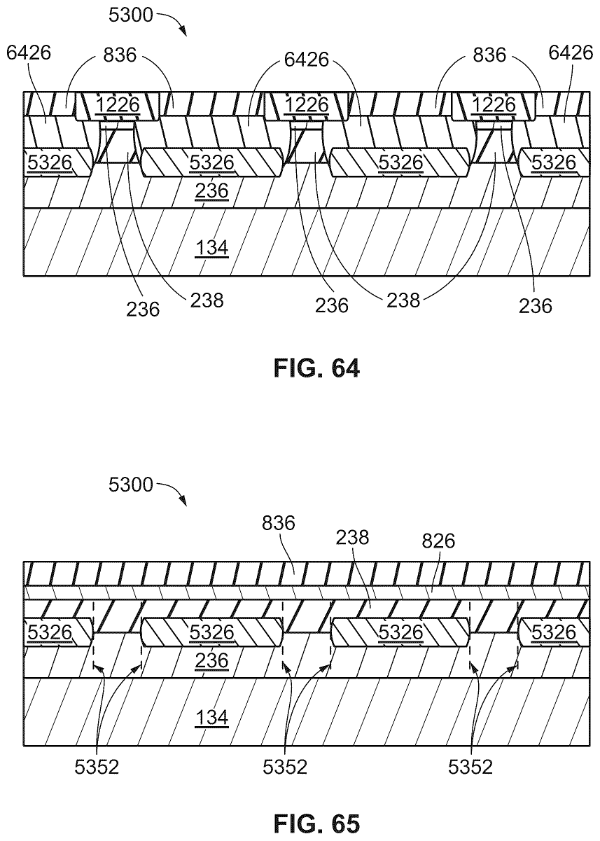

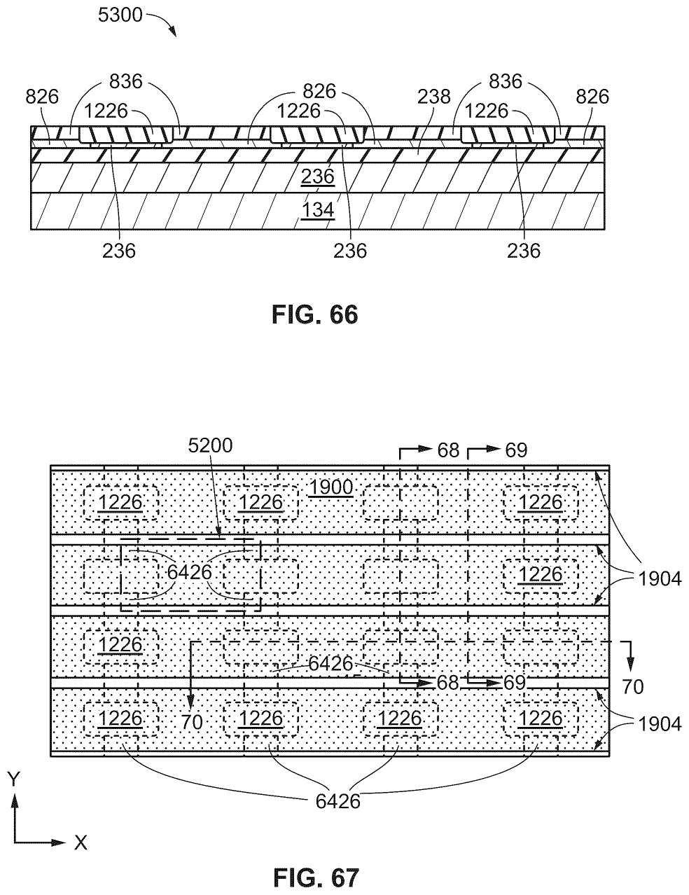

FIGS. 64 to 66 include cross-sectional views of the workpiece 5300 after link regions 6426 are formed below the link openings 6306 and the link mask 6300 is removed. The link regions 6426 have the same conductivity type as the buried shields 5326 and the body contact regions 1226. In an implementation, the links regions 6426 are p-type doped. The link regions 6426 can be at any depth and have any of the peak dopant concentrations as previously described with respect to the link regions 1626 for Design 1. FIG. 64 is along the sectioning line 64-64 in FIG. 63, FIG. 65 is along the sectioning line 65-65 in FIG. 63, and FIG. 66 is along the sectioning line 66-66 in FIG. 63.

As compared to the link regions 1626 in Design 1, the link regions 6426 are shifted by a half unit cell in the Y-direction. The link regions 6426 underlap portions of the body contact regions 1226 and the source region 836; however, the centers of the link regions 6426 do not underlap the centers of the body contact regions 1226. In the same or different implementation, from a top view, each of centers of the link regions 6426 can be half way between centers of corresponding pairs body contact regions 1226 that lie closer to the top and bottom of FIG. 63.

Referring to FIGS. 63 to 66, in this particular implementation, the link regions 6426 are aligned to edges of the gap regions 5352. In other implementations, the link regions 6426 may extend slightly over the caplet-shaped features or may not extend completely to the gap regions 5352. The link regions 6426 may extend slightly under the link mask 6300 adjacent to the link openings 6306 due to implant scattering.

The link regions 6426 electrically couple to the buried shields 5326 and the body contact regions 1226 to one another. In an implementation, the link regions 6426 electrically connect the buried shields 5326 and the body contact regions 1226 to one another. Each of the link regions 6426 has a pair of corresponding body contact regions 1226 where portions of the corresponding body contact regions 1226 overlap parts of the particular link region 6426. Centers of the link regions 6426 underlap portions of the source region 836. The link regions 6426 extend through the carrier accumulation region 238 to any depth within the buried shields 5326. In any one of the previous or different implementations, the link regions 6426 physically contact the buried shields 5326 and the body contact regions 1226. In other implementations, the link regions 6426 can be electrically coupled to the body contact regions 1226 through small portions of the body regions 826. In either case, the link regions 6426 are adjacent to the body contact regions 1226 in Design 3.

An anneal can be performed to activate dopants with respect to the previously described doping operations. The use of a graphite capping layer, soak time, temperature, and gas for the anneal can be any of those previously described with respect to the anneal in Design 1. The anneal can be performed before or after forming gate trenches as described below. The anneal can be performed before forming a gate dielectric layer because a material within the gate dielectric layer may not be able to withstand the temperature used for the anneal. The order of performing the doping operations can be of those previously described with respect to Design 1.

FIG. 67 includes a top view of a gate trench mask 1900 over the workpiece 5300. The gate trench mask 1900 defines gate trench openings 1904 that are used to define gate trenches. The gate trench openings 1904 can be in the shape of stripes that have lengths that extend in the X-direction. The gate trench mask 1900 can have any of the constructions and compositions as previously described with respect to the gate trench mask 1900 in Design 1.

Positional relationships between the gate trench openings 1904 and the buried shields 5326, the body region 826, the source region 836, and the body contact regions 1226 are the same as described with respect to the buried shield 426, the body region 826, the source region 836, and the body contact regions 1226, respectively, as described with respect to Design 1.

The link regions 6426 are farther into the workpiece 5300 as compared to the body contact regions 1226 and spaced apart from the major surface 126. The link regions 6426 have substantially rectangular shapes and lengths that extend in the Y-direction in FIG. 67. The gate trenches openings 1904 overlap and are spaced apart from the link regions 6426 in the Z-direction (into and out of FIG. 67). In the same or different implementation, centers of the widths (as measured in the Y-direction) of the gate trench openings 1904 are centered over centers of the link regions 6426.

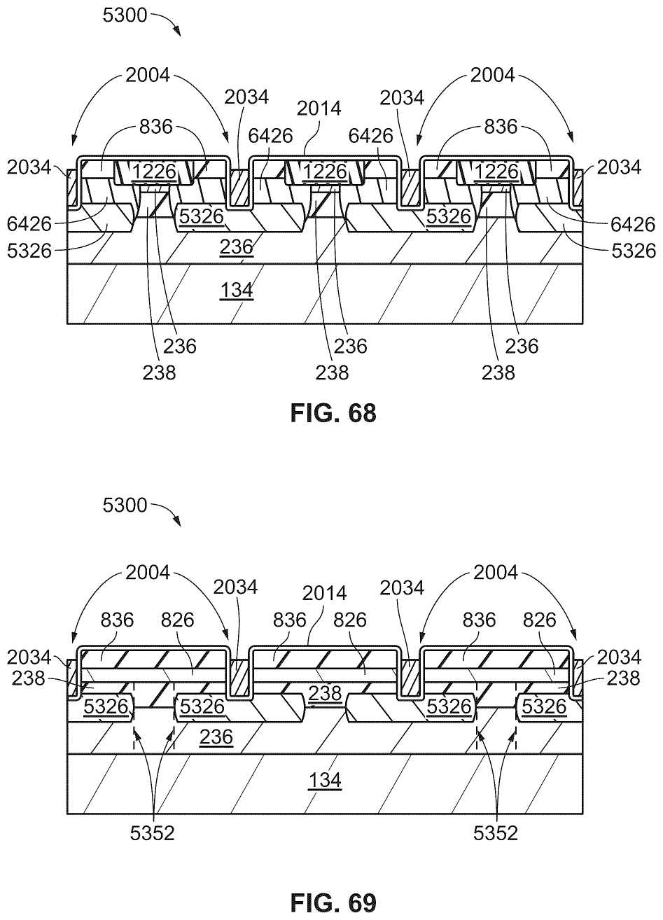

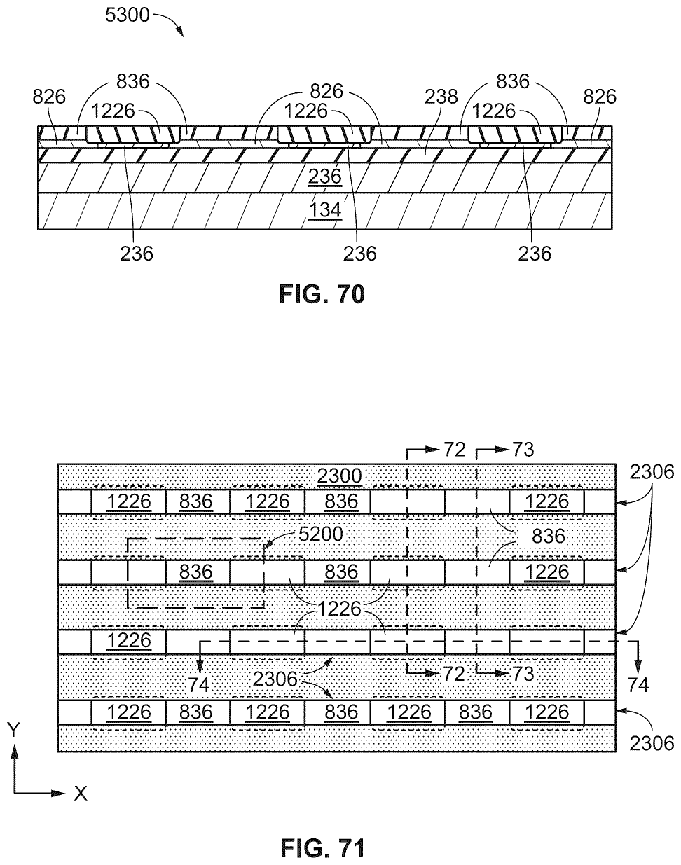

FIGS. 68 to 70 include cross-sectional views of the workpiece 5300 after defining the gate trenches 2004, removing the gate trench mask 1900, forming the gate dielectric layer 2014 and the gate electrodes 2034, and recessing the gate electrodes 2034 within the gate trenches 2004. FIG. 68 is along the sectioning line 68-68 in FIG. 67, FIG. 69 is along the sectioning line 69-69 in FIG. 67, and FIG. 70 is along the sectioning line 70-70 in FIG. 67. Other than the link regions 6426, the positional relationships between any of the gate trenches 2004, the gate dielectric layer 2014, the gate electrodes 2034, and other doped regions and layers are addressed with respect to Design 1.

The gate trenches 2004 may extend to a depth within or through the link regions 6426. In the same or different implementation, centers of the widths (as measured in the Y-direction) of the gate trenches 2004 extend through centers of the link regions 6426. Hence, Design 3 has gate trench-centered link regions.

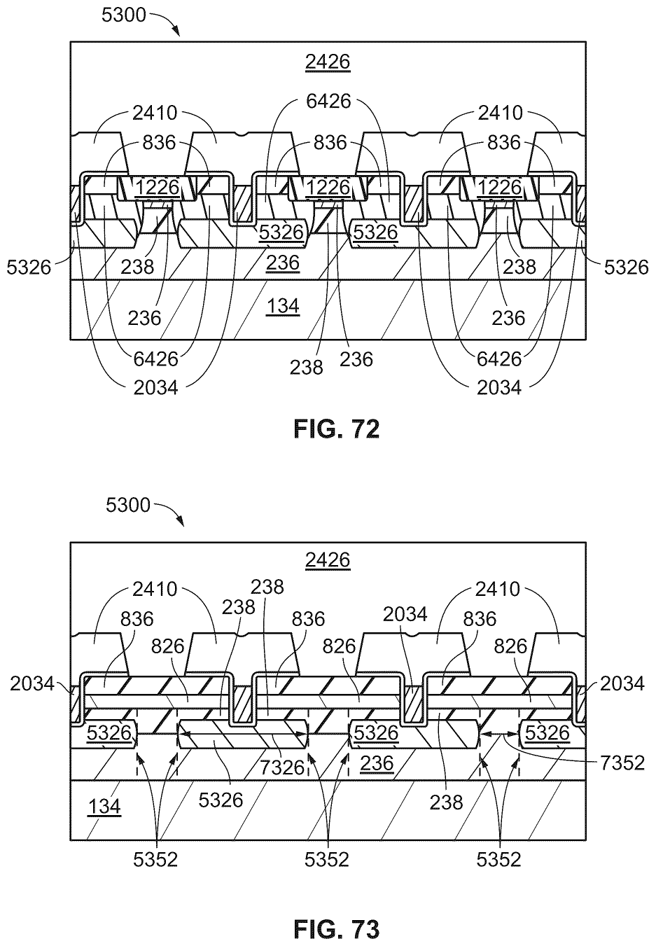

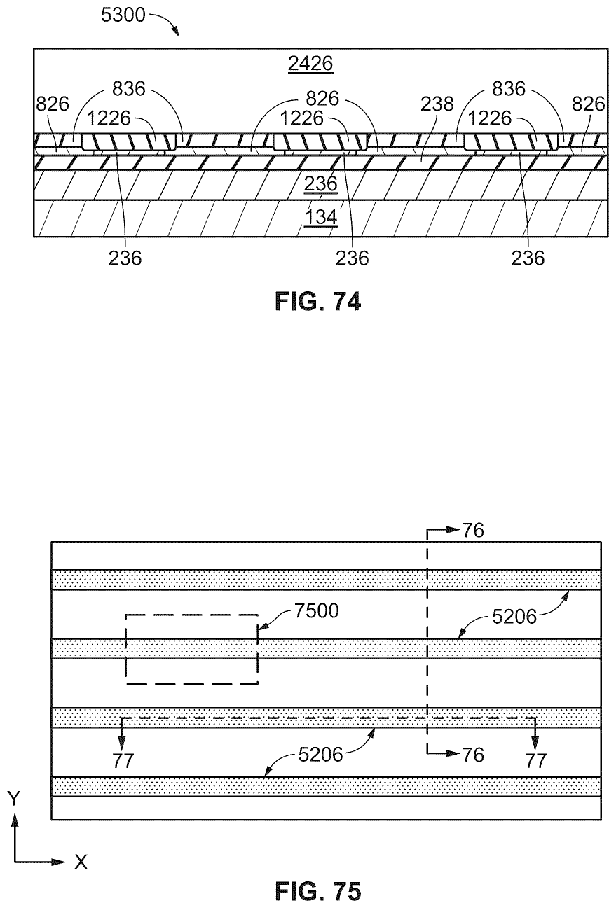

Referring to FIGS. 71 to 74, the ILD layer 2410 can be formed over the workpiece 5300, the contact mask 2300 can be formed over the ILD layer 2410 and includes the contact openings 2306 to expose portions of the ILD layer 2410. The contact mask 2300 can be removed after the ILD layer 2410 is patterned to define contact openings extending though the ILD layer 2410. The source terminal 2426 and a gate terminal (not illustrated) can be formed. FIG. 72 is along the sectioning line 72-72 in FIG. 71, FIG. 73 is along the sectioning line 73-73 in FIG. 71, and FIG. 74 is along the sectioning line 74-74 in FIG. 71.

Referring to FIG. 73, the widths of portions of buried shields 5326 between immediately adjacent gap regions 5352 are illustrated by a dimension 7326, and the widths of the gap regions 5352 are illustrated by a dimension 7352. Although not illustrated, the transistor structures illustrated in FIG. 73 have further dimensions that are measured at locations corresponding to the dimensions 2726 and 2738 in FIG. 27.

The transistor structures of the power transistor within the workpiece 5300 can have the same majority carrier flow characteristics, and aspect and buried shield-to-gap ratios as illustrated in FIGS. 27 and 73 and described with respect to the transistor structures of the power transistor within the workpieces 100 and 5300.

### Design 4: Link Regions Staggered With Respect to Body Contact Regions and Gate Trench-Centered Link Regions

The buried shield mask, the body/source mask, and the body contact mask for Design 4 are the same as the buried shield mask, the body/source mask, and the body contact mask, respectively, for Design 3. The substrate 120 is processed as previously described and illustrated in FIGS. 1 and 2.

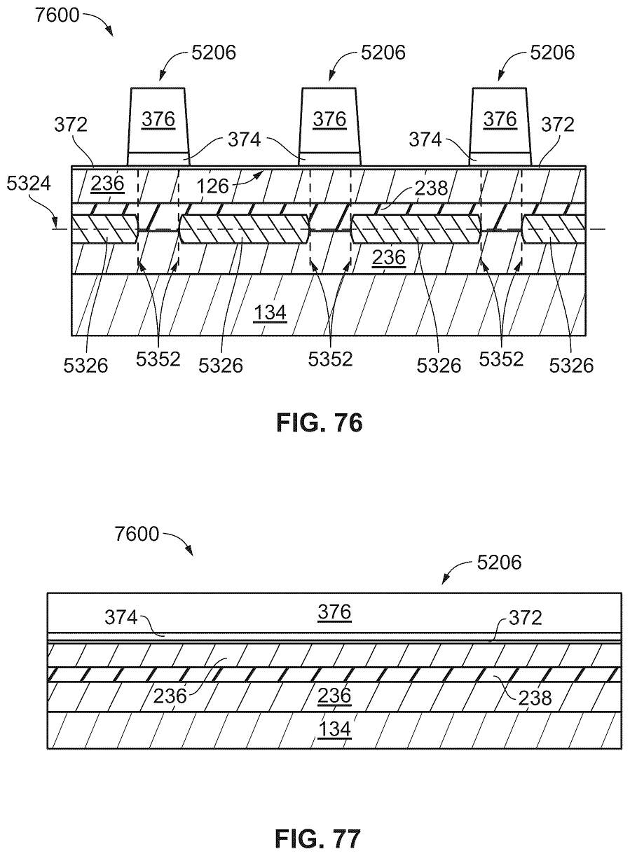

The buried shield mask including the mask members 5206 in FIG. 75 are formed over the substrate 120. FIG. 75 includes a unit cell 7500. Many other unit cells are present but not identified in FIG. 75. The unit cells that are immediately adjacent to the right, left, above and below the unit cell 7500 are mirror images of the unit cell 7500. FIGS. 76 and 77 include cross-sectional views of a workpiece 7600 after the buried shields 5326 are formed. The mask members 5206 remain in these figures and are removed in a subsequent process step. FIG. 76 is along the sectioning line 76-76 in FIG. 75, and FIG. 77 is along the sectioning line 77-77 in FIG. 75.

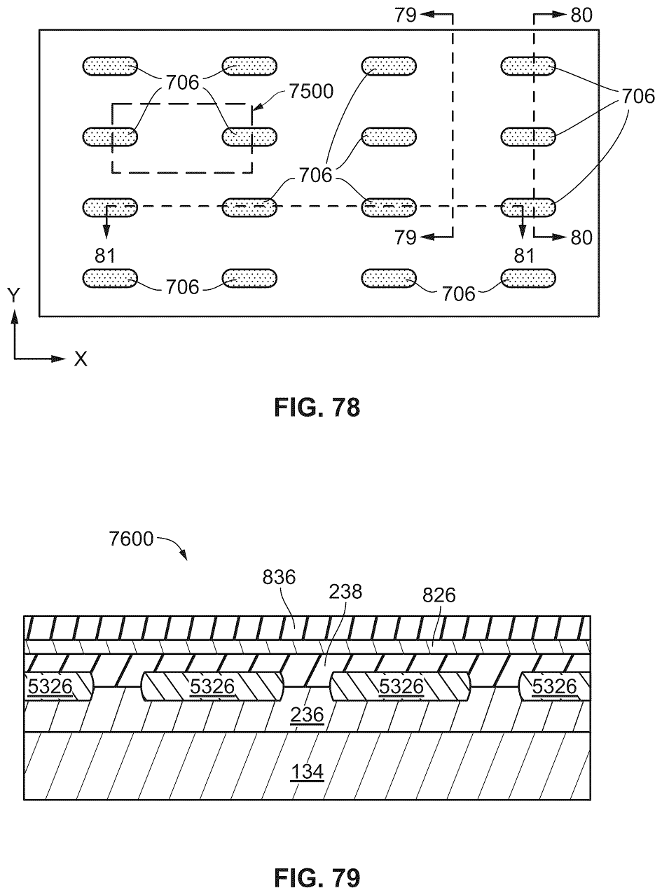

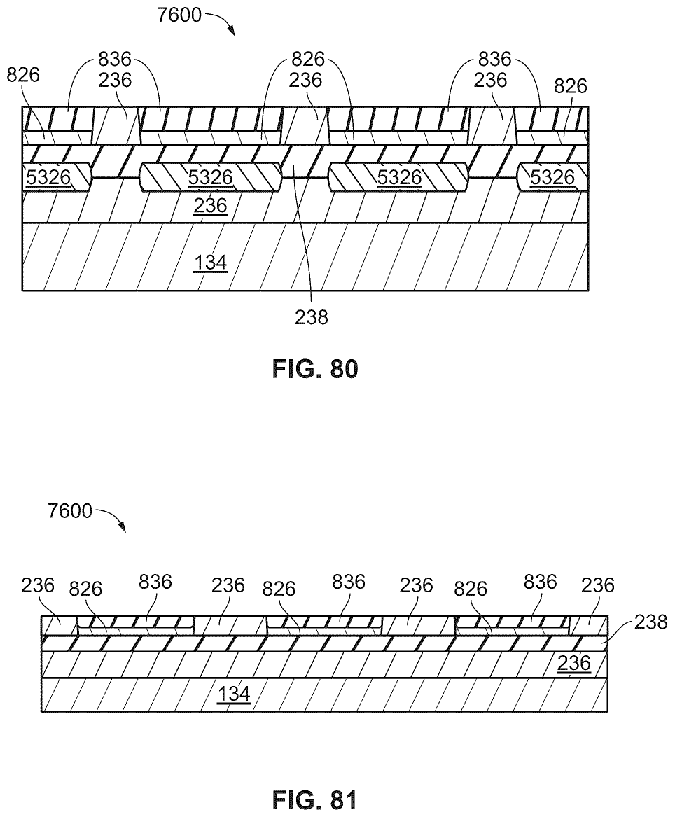

For the body/source mask including the mask members 706 in FIG. 78 are formed over the workpiece 7600. FIGS. 79 to 81 include cross-sectional views of the workpiece 7600 after the body region 826 and the source region 836 are formed and the mask members 706 are removed. FIG. 79 is along the sectioning line 79-79 in FIG. 78, FIG. 80 is along the sectioning line 80-80 in FIG. 78, and FIG. 81 is along the sectioning line 81-81 in FIG. 78.

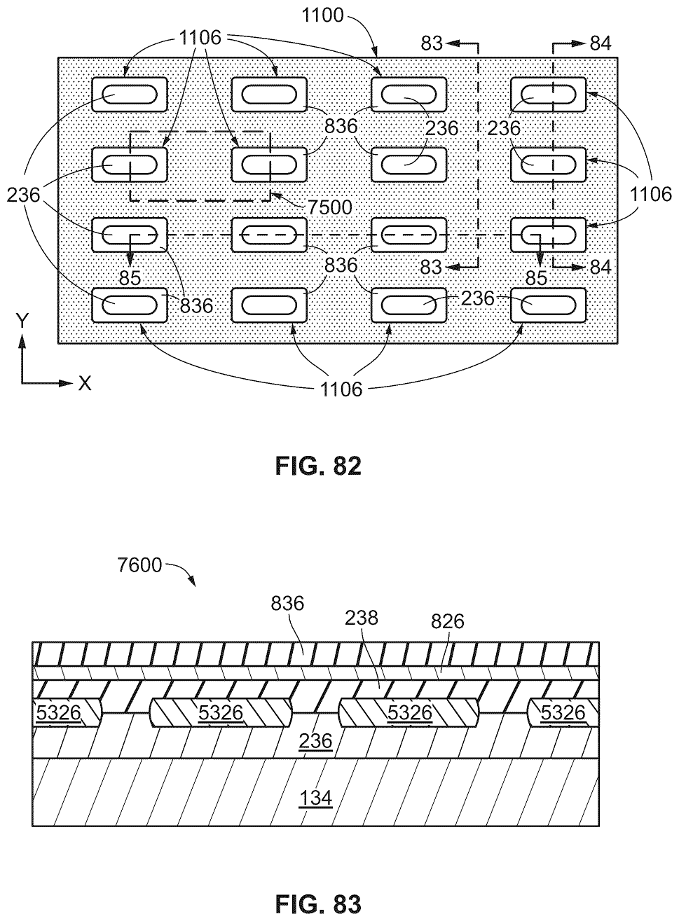

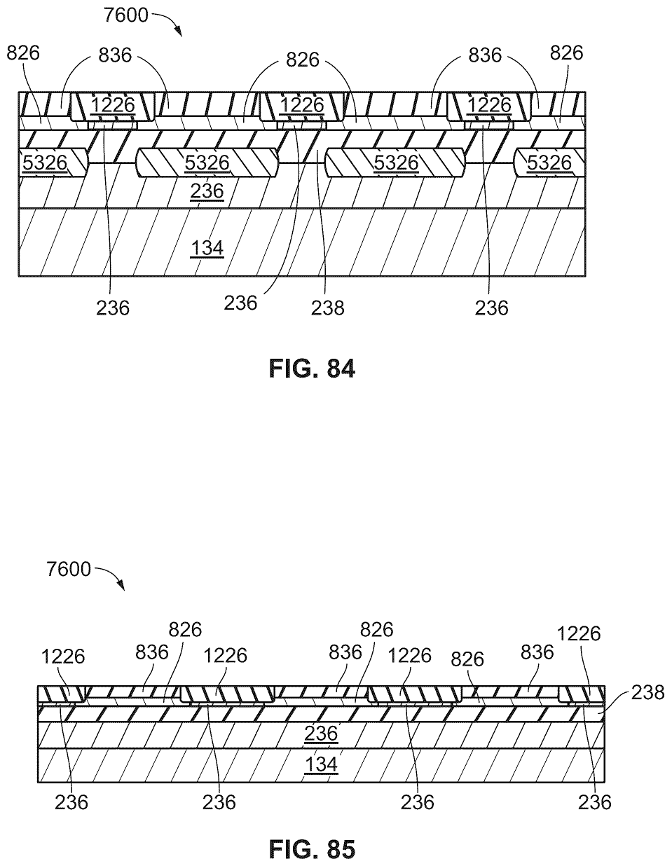

The body contact mask 1100 that defines the body contact openings 1106 is formed over the workpiece 7600 in FIG. 82. FIGS. 83 to 85 include cross-sectional views of the workpiece 7600 after the body contact regions 1226 are formed and the body contact mask 1100 is removed. FIG. 83 is along the sectioning line 83-83 in FIG. 82, FIG. 84 is along the sectioning line 84-84 in FIG. 82, and FIG. 85 is along the sectioning line 85-85 in FIG. 82.

The buried shields 5326, the body region 826, the source region 836, and the body contact regions 1226 in Design 4 are the same as the buried shields 5326, the body region 826, the source region 836, and the body contact regions 1226, respectively, in Design 3. The relationships between the buried shields 5326, the body region 826, the source region 836, and the body contact regions 1226 as described with respect to Design 3 also apply to the relationships between the buried shields 5326, the body region 826, the source region 836, and the body contact regions 1226 in Design 4.

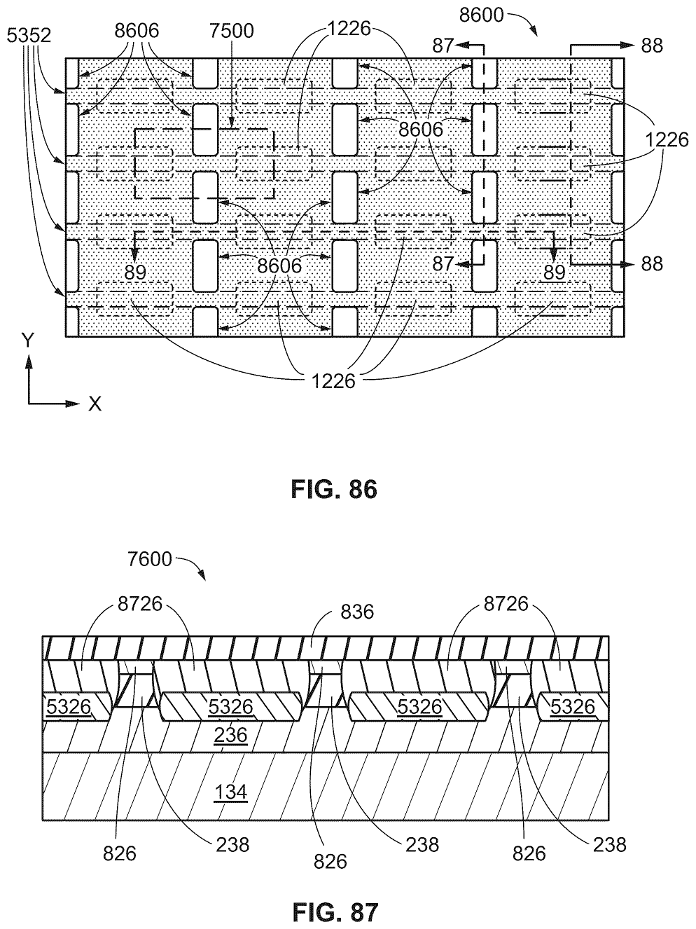

FIG. 86 includes a top view of a link mask 8600. The link mask 8600 can be formed and define link openings 8606 where dopant for link regions will be introduced into the workpiece. In FIG. 86, not all the link openings 8606, body contact regions 1226, and exposed portions of the source region 836 are identified with reference numbers to simplify understanding of the mask design. The link mask 8600 can have any of the constructions and compositions as previously described with respect to the link mask 1500.

The locations of the link openings 8606 in FIG. 86 for Design 4 are shifted by half of a unit cell in the X-direction as compared to the locations of the link openings 6306 in FIG. 63 for Design 3. The locations of the link openings 8606 in FIG. 86 for Design 4 are shifted by half of a unit cell in the X-direction and half of a unit cell in the Y-direction as compared to the locations of the link openings 1506 in FIG. 15 for Design 1.

In an implementation, the link openings 8606 are not concentric with the body contact regions 1226. In the same or different implementation, portions of the source region 836 underlap the link openings 8606, and no portion of the body contact regions 1226 underlap the link openings 8606.

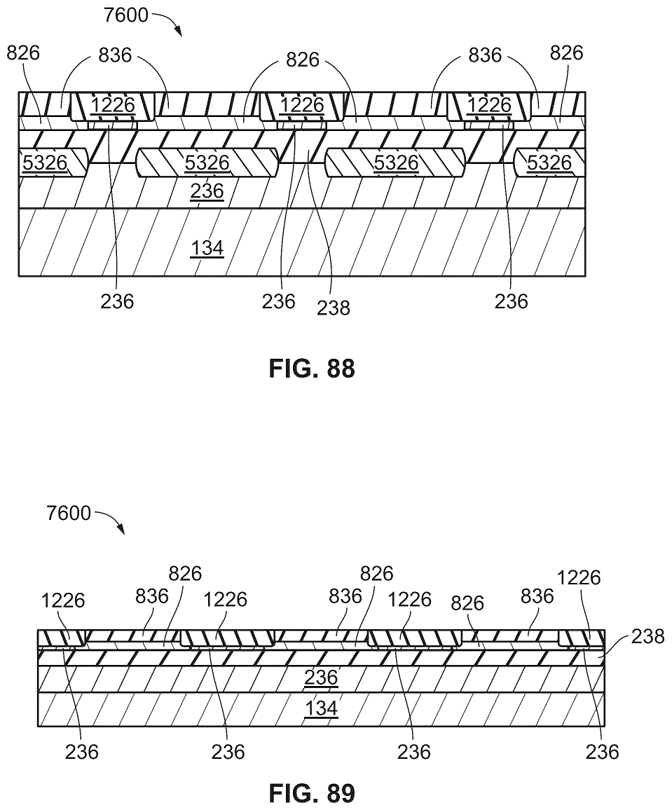

FIGS. 87 to 89 include cross-sectional views of the workpiece 7600 after link regions 8726 are formed and the link mask 8600 is removed. FIG. 87 is along the sectioning line 87-87 in FIG. 86, FIG. 88 is along the sectioning line 88-88 in FIG. 86, and FIG. 89 is along the sectioning line 89-89 in FIG. 86. The link regions 8726 have the same conductivity type as the buried shields 5326 and the body contact regions 1226. In an implementation, the links regions 8726 are p-type doped. The link regions 8726 can be at any depth and have any of the peak dopant concentrations as previously described with respect to the link regions 1626 for Design 1.

When comparing the relative locations of the link regions 8726 and the body contact regions 1226 for Design 4 to the relative locations of the link regions 6426 and the body contact regions 1226 for Design 3, the link regions 8726 are shifted by half of a unit cell in the X-direction with respect to the body contact regions 1226. When comparing the relative locations of the link regions 8726 and the body contact regions 1226 in FIG. 86 for Design 4 to the relative locations of the link regions 1626 and the body contact regions 1226 for Design 1, the link openings 8606 are shifted by half of a unit cell in the X-direction and half of a unit cell in the Y-direction with respect to the body contact regions 1226.

The link regions 8726 electrically couple the buried shields 5326 and the body contact regions 1226 to one another via portions of the body region 826. In an implementation, the link regions 8726 electrically connect the buried shields 5326 and the body contact regions 1226 to one another via portions of the body region 826. In the same or different implementation, the link regions 8726 physically contact the buried shields 5326 and the body region 826.

In an implementation, the link regions 8726 are not concentric with the body contact regions 1226. Centers of the link regions 8726 underlap portions of the source region 836; however, the centers of the link regions 6426 do not underlap the centers of the body contact regions 1226. The link regions 8726 extend through the portions of the carrier accumulation region 238 to any depth within the buried shields 5326. In the same or different implementation, portions of the source region 836 overlap the link regions 8726, and no portion of the body contact regions 1226 overlap the link regions 8726. Hence, Design 4 has the link regions 8726 staggered with respect to the body contact regions 1226.

An anneal can be performed to activate dopants with respect to the previously described doping operations. The use of a graphite capping layer, soak time, temperature, and gas for the anneal can be any of those previously described with respect to the anneal in Design 1. The anneal can be performed before or after forming gate trenches as described below. The anneal can be performed before forming a gate dielectric layer because a material within the gate dielectric layer may not be able to withstand the temperature used for the anneal. The order of performing the doping operations can be of those previously described with respect to Design 1.

Many doping operations have been described previously. The order of performing the doping operations after forming the semiconductor layer 134 can be changed. The order of performing the doping operations can be of those previously described with respect to Design 1.

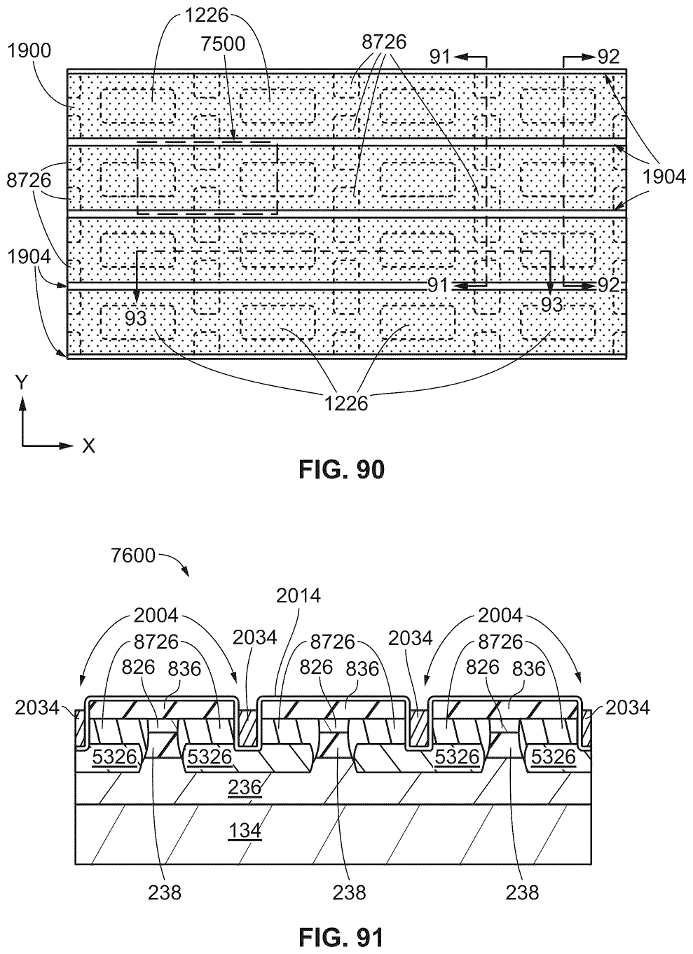

FIG. 90 includes a top view of a gate trench mask 1900 over the workpiece 7600. The gate trench mask 1900 defines gate trench openings 1904 that are used to define gate trenches. The gate trench openings 1904 can be in the shape of stripes that have lengths that extend in the X-direction. The gate trench mask 1900 can have any of the constructions and compositions as previously described with respect to the gate trench mask 1900 in Design 1.

Positional relationships between the gate trench openings 1904 and the buried shields 5326, the body region 826, the source region 836, and the body contact regions 1226 are the same as described with respect to the buried shield 426, the body region 826, the source region 836, and the body contact regions 1226, respectively, as described with respect to Design 1.

The link regions 8726 are farther into the workpiece 5300 as compared to the body contact regions 1226 and spaced apart from the major surface 126. The link regions 8726 have substantially rectangular shapes and lengths that extend in the Y-direction in FIG. 90. The gate trenches openings 1904 overlap and are spaced apart from the link regions 8726 in the Z-direction (into and out of FIG. 90). In the same or different implementation, centers of the widths (as measured in the Y-direction) of the gate trench openings 1904 are centered over centers of the link regions 6426.

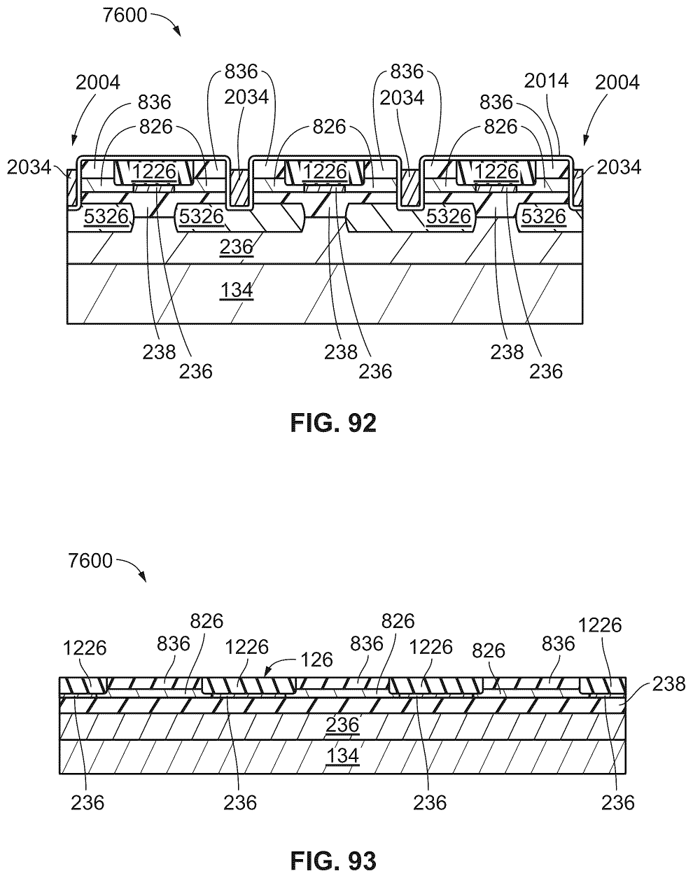

FIGS. 91 to 93 include cross-sectional views of the workpiece 7600 after defining the gate trenches 2004, removing the gate trench mask 1900, forming the gate dielectric layer 2014 and the gate electrodes 2034, and recessing the gate electrodes 2034 within the gate trenches 2004. FIG. 91 is along the sectioning line 91-91 in FIG. 90, FIG. 92 is along the sectioning line 92-92 in FIG. 90, and FIG. 93 is along the sectioning line 93-93 in FIG. 90. Other than the link regions 8726, the positional relationships between any of the gate trenches 2004, the gate dielectric layer 2014, the gate electrodes 2034, and other doped regions and layers are addressed with respect to Design 1.

The gate trenches 2004 may extend to a depth within or through the link regions 8726. In the same or different implementation, centers of the widths (as measured in the Y-direction) of the gate trenches 2004 extend through centers of the link regions 6426. Hence, Design 4 has gate trench-centered link regions.

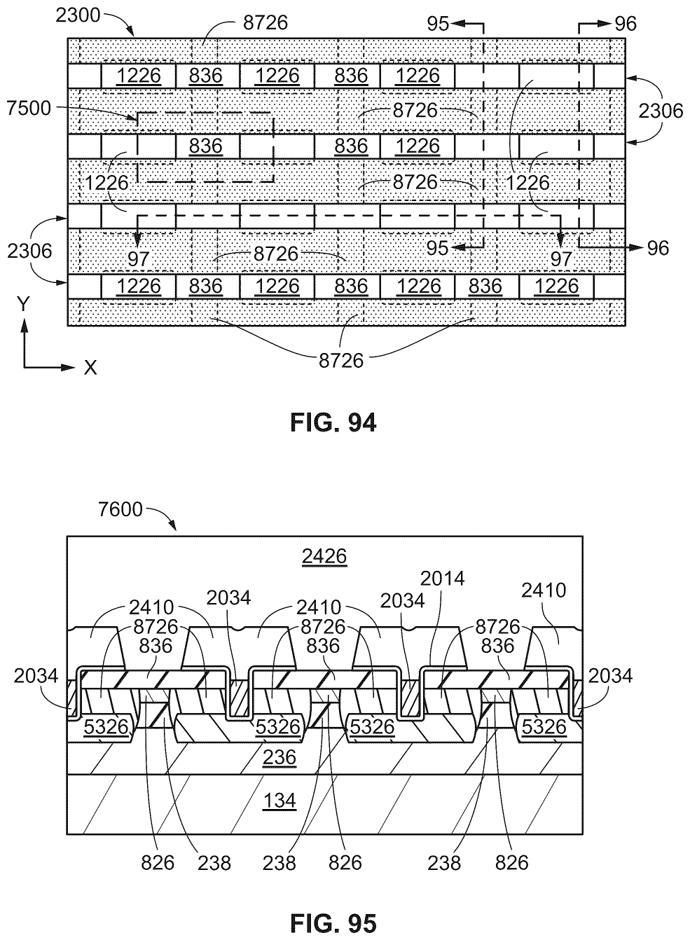

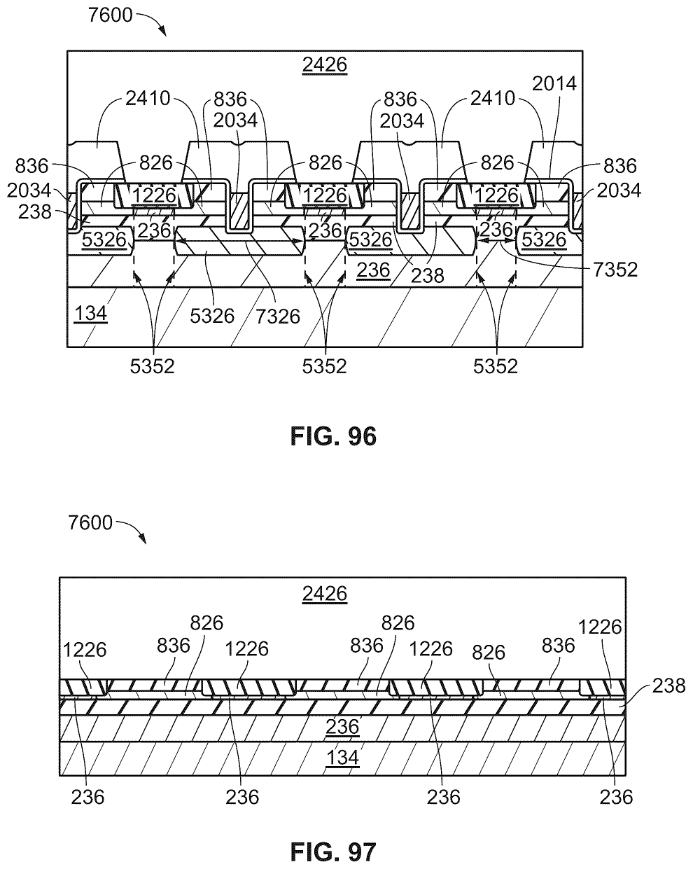

Referring to FIGS. 94 to 97, the ILD layer 2410 can be formed over the workpiece 7600, a contact mask 2300 can be formed over the ILD layer 2410 and includes the contact openings 2306 to expose portions of the ILD layer 2410. The contact mask 2300 can be removed after the ILD layer 2410 is patterned to define contact openings extending though the ILD layer 2410. The source terminal 2426 and a gate terminal (not illustrated) can be formed. FIG. 95 is along the sectioning line 95-95 in FIG. 94, FIG. 96 is along the sectioning line 96-96 in FIG. 94, and FIG. 97 is along the sectioning line 97-97 in FIG. 94.

Referring to FIG. 96, the widths of portions of buried shields 5326 between immediately adjacent gap regions 5352 are illustrated by the dimension 7326, and the widths of the gap regions 5352 are illustrated by the dimension 7352. Although not illustrated, the transistor structures illustrated in FIG. 96 have further dimensions that are measured at locations corresponding to the dimensions 2726 and 2738 in FIG. 27.

The transistor structures of the power transistor within the workpiece 7600 can have the same majority carrier flow characteristics, and aspect and buried shield-to-gap ratios as illustrated in FIGS. 27 and 73 and described with respect to the transistor structures of the power transistor within the workpieces 100 and 5300.

### Relative Shifting of Masks Between Designs

For Designs 2 to 4, a mask at a particular point in the process is described with respect to shifting the mask by half of a unit cell in the X-direction, half of a unit cell in the Y-direction, or half of a unit cell in each of the X-direction and Y-direction. In an alternative embodiment, shifting of the mask can be by a value other than half or a direction other X-direction or the Y-direction.

With respect to the link regions 1626 in Design 1 and the link regions 4126 in Design 2, the link regions 1626 and 4126 can be moved with respect to the gap regions 452. In an implementation, the link regions 1626 and 4126 can be moved so that they are not centered over the gap regions 452. In the same or different implementation, each of the link regions 1626 and 4126 can extend across all of the widths (as measured in the Y-direction) of its corresponding gap region 452.

With respect to the link regions 6426 in Design 3 and the link regions 8726 in Design 4, the link regions 6426 and 8726 can be moved with respect to the gate trenches 2004. In an implementation, the link regions 6426 and 8726 can be moved so that they are not centered about the gate trenches 2004. In the same or different implementation, portions of each of the link regions 6426 and 8726 can lie along opposite sidewalls of its corresponding gate trench 2004.

With respect to the link regions 1626 in Design 1 and the link regions 6426 in Design 3, the link regions 1626 and 6426 can be moved with respect to the body contact regions 1226. In an implementation, the link regions 1626 and 6426 can be moved provided at least parts of the link regions 1626 and 6426 physically contact the body contact regions 1226.

With respect to the link regions 4126 in Design 2 and the link regions 8726 in Design 4, the link regions 4126 and 8726 can be moved with respect to the body contact regions 1226. In an implementation, the link regions 4126 and 8726 can be moved provided at least part of the link regions 4126 and 8726 are spaced apart and do not physically contact the body contact regions 1226.

### Comparisons of Designs 1 to 4

In Design 1, the link regions 1626 can be gap-centered, and the body contact regions 1226 can overlap the link regions 1626. The locations of the link regions 1626 allow for a relatively low resistance connection between the buried shield 426 and the source terminal 2426.

In Design 2, the link regions 6426 can be gap-centered, and the link regions 6426 can be staggered with respect to the body contact regions 1226. Design 2 can be helpful to reduce or eliminate the risk of punchthrough between the source region 836 when the body contact regions 1226 overlap the gap regions without any other p-type doped region between the gap regions 452 and the body contact regions 1226.

In Design 3, the link regions 6426 can be centered with respect to the gate trenches 2004, and the body contact regions 1226 can overlap the link regions 1626. The locations of the link regions 6426 allow for a relatively low resistance connection between the buried shields 5326 and the source terminal 2426. Portions of the link regions 6426 lie along sidewalls of the gate trenches 2004. The channel regions of the transistor structures can be blocked while the gap regions 5352 between the buried shields 5326 are not blocked. (For instance, compare the area of the mask members 5206 of the buried shield mask in FIG. 52 of Design 3 and the area of the mask members 306 of the buried shield mask in FIG. 3 of Design 1.) Consequently, there is an inherent tradeoff between trench-centered link designs and gap-centered link designs. The primary contribution to the on-state drain-to-source resistance (RDS_{ON}) in the portion of the transistor structure above the buried shields 5326 comes from the channel regions, the carrier accumulation region 238, and the gap regions 5352. With regards to each other, trench-centered link designs have lower gap resistance and higher channel resistance as compared to equivalent gap-centered link designs. As the temperature of operation increases, the channel resistance decreases because of its negative temperature coefficient, and the gap resistance increases because of its positive temperature coefficient. Therefore, the benefits of one type of link design over another is not only a function of physical design parameters such cell geometry and doping concentration but is also dependent upon the targeted temperature during normal operation.

In Design 4, the link regions 8726 can be centered with respect to the gate trenches 2004, and the link regions 8726 can be staggered with respect to the body contact regions 1226. The locations of the link regions 8726 allow for a relatively low resistance connection between the buried shield 426 and the source terminal 2426. Portions of the link regions 8726 lie along opposite sidewalls of the gate trenches 2004.

The implementations described herein have benefits as compared to other electronic devices. The aspect ratio (dimension 2726 to dimension 2738 in FIG. 27) of at least 1.5:1, the buried shield-to-gap ratio of at least 2:1, or both allow the power transistor to withstand a relatively longer short-circuit event while maintaining acceptable specific on-state resistance for the power transistor. Each of the designs have a relatively large area where the source region and body contact regions are physically contacted by the source terminal. Four different designs are disclosed and allow more flexibility for skilled artisans to tailor better a particular physical design to meet the needs and desires for a particular application.

Many different aspects and implementations are possible. Some of those aspects and implementations are described below. After reading this specification, skilled artisans will appreciate that those aspects and implementations are only illustrative and do not limit the scope of the inventive concepts. Implementations may be in accordance with any one or more of the implementations as listed below.

Implementation 1. An electronic device can include a transistor structure. The transistor structure can include a substrate defining a gate trench that extends to a gate trench depth from a major surface of the substrate; a carrier accumulation region having a first conductivity type; a body region having a second conductivity type opposite the first conductivity type, wherein the body region overlaps the carrier accumulation region; a buried shield having the second conductivity type, wherein the buried shield is spaced apart from the body region by at least a portion of the carrier accumulation region; and a gap region having the first conductivity type, wherein the gap region is defined at least in part by the buried shield and has a gap region width that is a narrowest width of the gap region as measured in a measuring direction that is parallel to the major surface and perpendicular to the gate trench depth. The transistor structure can have an aspect ratio that is a ratio of a lateral dimension to a vertical dimension, the lateral dimension can be measured in the measuring direction of the gap region and is a second distance between: a first point within the buried shield that underlaps an intersection of the body region, the carrier accumulation region, and the gate trench, and a second point where the buried shield within the transistor structure extends farthest toward the gap region. The vertical dimension can be a first distance between the body region and the buried shield along the gate trench in a first direction perpendicular to the major surface. The aspect ratio is at least 1.5:1.

Implementation 2. The electronic device of Implementation 1, wherein the transistor structure is adapted such that the carrier accumulation region is fully depleted when the gap region is not fully depleted.

Implementation 3. The electronic device of Implementation 1 further includes a carrier distribution layer, wherein at least 10% of the buried shield overlaps the carrier distribution layer.

Implementation 4. The electronic device of Implementation 3 further includes a semiconductor layer having the first conductivity type and is spaced apart from the buried shield by the carrier distribution layer.

Implementation 5. The electronic device of Implementation 1 further includes a carrier distribution layer, wherein, within the transistor structure, all of the buried shield overlaps the carrier distribution layer.

Implementation 6. The electronic device of Implementation 1 further includes a source region having the first conductivity type and overlapping the body region.

Implementation 7. The electronic device of Implementation 6 further includes a link region having the second conductivity type and electrically coupled to the body region and the buried shield, wherein the link region under laps at least part of the source region.

Implementation 8. An electronic device can include a substrate defining a gate trench that extends to a gate trench depth from a major surface of the substrate; and a gap region having a first conductivity type, wherein the gap region has a gap region width that is a narrowest width of the gap region as measured in a measuring direction that is parallel to the major surface and perpendicular to the gate trench depth. The electronic device can further include a buried shield having a second conductivity type opposite the first conductivity type, wherein the buried shield has a buried shield width that is a widest width of the buried shield as measured in the measuring direction. The gap region can be defined at least in part by the buried shield, the buried shield can underlap the gate trench, a buried shield-to-gap ratio can be a ratio of the buried shield width to the gap region width, and the buried shield-to-gap ratio can be at least 2:1.

Implementation 9. The electronic device of Implementation 8, wherein the buried shield contacts the gate trench.

Implementation 10. The electronic device of Implementation 9 further includes a gate electrode within the gate trench, wherein the gate electrode is recessed within the gate trench.

Implementation 11. The electronic device of Implementation 9 further includes a carrier distribution layer having the first conductivity type and underlapping at least 10% of the buried shield.

Implementation 12. The electronic device of Implementation 11 further includes a semiconductor layer having the first conductivity type and underlapping the carrier distribution layer.

Implementation 13. The electronic device of Implementation 11 further includes a carrier accumulation region having the first conductivity type, wherein a peak dopant concentration of the carrier accumulation region is greater than a peak dopant concentration of the carrier distribution layer.

Implementation 14. An electronic device can include a source region having a first conductivity type; a body region having a second conductivity type opposite the first conductivity type and can underlap the source region; a carrier accumulation region having the first conductivity type and can underlap the body region; a buried shield having the second conductivity type and can underlap at least a portion of the carrier accumulation region; and a link region having the second conductivity type and can be electrically coupled to the body region and the buried shield, wherein the link region can underlap at least part of the source region.

Implementation 15. The electronic device of Implementation 14, wherein the link region contacts the body region and the buried shield.

Implementation 16. The electronic device of Implementation 14 further includes a substrate having a major surface, wherein a gate trench extends from the major surface, and the link region lies along a sidewall of the gate trench.

Implementation 17. The electronic device of Implementation 14 further includes a substrate having a major surface, wherein a gate trench extends from the major surface, and the link region is spaced apart from a sidewall of the gate trench.

Implementation 18. The electronic device of Implementation 14 further includes a body contact region of the second conductivity type that is electrically coupled to the body region.

Implementation 19. The electronic device of Implementation 18, wherein the link region is electrically coupled to the body contact region, wherein the link region is spaced apart from the body contact region by least part of the body region.

Implementation 20. The electronic device of Implementation 18, wherein the link region is electrically coupled to the body contact region via the body region.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that may cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations may also be provided in combination in a single implementation, and conversely, various features that are, for brevity, described in the context of a single implementation, may also be provided separately or in any subcombination. Further, reference to values stated in ranges includes each and every value within that range. Many other implementations may be apparent to skilled artisans only after reading this specification. Other implementations may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electronic device, comprising a transistor structure, wherein the transistor structure comprises:
a substrate defining a gate trench that extends to a gate trench depth from a major surface of the substrate;
a carrier accumulation region having a first conductivity type;
a body region having a second conductivity type opposite the first conductivity type, wherein the body region overlaps the carrier accumulation region;
a buried shield having the second conductivity type, wherein the buried shield is spaced apart from the body region by at least a portion of the carrier accumulation region; and
a gap region having the first conductivity type, wherein the gap region is defined at least in part by the buried shield and has a gap region width that is a narrowest width of the gap region as measured in a measuring direction that is parallel to the major surface and perpendicular to the gate trench depth,
wherein:
the transistor structure has an aspect ratio that is a ratio of a lateral dimension to a vertical dimension,
the lateral dimension is measured in the measuring direction of the gap region and is a second distance between:
a first point within the buried shield that underlaps an intersection of the body region, the carrier accumulation region, and the gate trench, and
a second point where the buried shield within the transistor structure extends farthest toward the gap region,
the vertical dimension is a first distance between the body region and the buried shield along the gate trench in a first direction perpendicular to the major surface, and
the aspect ratio is at least 1.5:1.

2. The electronic device of claim 1, wherein the transistor structure is adapted such that the carrier accumulation region is fully depleted when the gap region is not fully depleted.

3. The electronic device of claim 1, further comprising a carrier distribution layer, wherein at least 10% of the buried shield overlaps the carrier distribution layer.

4. The electronic device of claim 3, further comprising a semiconductor layer having the first conductivity type and is spaced apart from the buried shield by the carrier distribution layer.

5. The electronic device of claim 1, further comprising a carrier distribution layer, wherein, within the transistor structure, all of the buried shield overlaps the carrier distribution layer.

6. The electronic device of claim 1, further comprising a source region having the first conductivity type and overlapping the body region.

7. The electronic device of claim 6, further comprising a link region having the second conductivity type and electrically coupled to the body region and the buried shield, wherein the link region underlaps at least part of the source region.

8. An electronic device, comprising:
a substrate defining a gate trench that extends to a gate trench depth from a major surface of the substrate;
a gap region having a first conductivity type, wherein the gap region has a gap region width that is a narrowest width of the gap region as measured in a measuring direction that is parallel to the major surface and perpendicular to the gate trench depth; and
a buried shield having a second conductivity type opposite the first conductivity type, wherein the buried shield has a buried shield width that is a widest width of the buried shield as measured in the measuring direction,
wherein:
the gap region is defined at least in part by the buried shield,
the buried shield underlaps the gate trench,
a buried shield-to-gap ratio is a ratio of the buried shield width to the gap region width, and
the buried shield-to-gap ratio is at least 2:1.

9. The electronic device of claim 8, wherein the buried shield contacts the gate trench.

10. The electronic device of claim 9, further comprising a gate electrode within the gate trench, wherein the gate electrode is recessed within the gate trench.

11. The electronic device of claim 9, further comprising a carrier distribution layer having the first conductivity type and underlapping at least 10% of the buried shield.

12. The electronic device of claim 11, further comprising a semiconductor layer having the first conductivity type and underlapping the carrier distribution layer.

13. The electronic device of claim 11, further comprising a carrier accumulation region having the first conductivity type, wherein a peak dopant concentration of the carrier accumulation region is greater than a peak dopant concentration of the carrier distribution layer.

14. An electronic device, comprising:
a source region having a first conductivity type;
a body region having a second conductivity type opposite the first conductivity type and underlapping the source region;
a carrier accumulation region having the first conductivity type and underlapping the body region;
a buried shield having the second conductivity type and underlapping at least a portion of the carrier accumulation region; and
a link region having the second conductivity type and electrically coupled to the body region and the buried shield, wherein the link region underlaps at least part of the source region.

15. The electronic device of claim 14, wherein the link region contacts the body region and the buried shield.

16. The electronic device of claim 14, further comprising a substrate having a major surface, wherein a gate trench extends from the major surface, and the link region lies along a sidewall of the gate trench.

17. The electronic device of claim 14, further comprising a substrate having a major surface, wherein a gate trench extends from the major surface, and the link region is spaced apart from a sidewall of the gate trench.

18. The electronic device of claim 14, further comprising a body contact region of the second conductivity type that is electrically coupled to the body region.

19. The electronic device of claim 18, wherein the link region is electrically coupled to the body contact region, wherein the link region is spaced apart from the body contact region by least part of the body region.

20. The electronic device of claim 18, wherein the link region is electrically coupled to the body contact region via the body region.
